(19) United States
(12) Patent Application Publication
(10) Pub. No.: US 2018/0326693 A1
(43) Pub. Date: Nov. 15, 2018

(54) LAMINATED FILM

(71) Applicant: FUJIFILM Corporation, Tokyo (JP)

(72) Inventors: Satoshi KUNIYASU, Kanagawa (JP); Tamotsu SAIKAWA, Kanagawa (JP)

(73) Assignee: FUJIFILM Corporation, Tokyo (JP)

(21) Appl. No.: 16/028,986

(22) Filed: Jul. 6, 2018

Related U.S. Application Data
(63) Continuation of application No. PCT/JP2016/088066, filed on Dec. 21, 2016.

(30) Foreign Application Priority Data
Jan. 7, 2016 (JP) 2016-001766

(51) Int. Cl. B32B 3/06; B32B 7/12; B32B 27/28; G02B 5/20; H01L 33/50

(52) U.S. Cl. CPC B32B 3/06; B32B 7/12; B32B 27/281; B32B 2307/422; H01L 33/505; B32B 2457/202; B32B 2307/7246; G02B 5/206

(57) ABSTRACT

A laminated film includes a functional layer laminate having a wavelength conversion layer, such as a quantum dot layer, and a gas barrier film laminated on both main surfaces and sandwiching the wavelength conversion layer, and an end face sealing layer covering a region from a portion of one main surface of the functional layer laminate to a portion of the other main surface including the entirety of end face of the functional layer laminate, in which the end face sealing layer has a build-up portion formed on the main surface of the functional layer laminate, and a width of the build-up portion measured from the end face is equal to or greater than 0.01 mm and equal to or smaller than 8% of a length of the main surface.

### CROSS-REFERENCE TO RELATED APPLICATIONS

This application is a Continuation of PCT International Application No. PCT/JP2016/088066 filed on Dec. 21, 2016, which claims priority under 35 U.S.C. § 119(a) to Japanese Patent Application No. 2016-001766 filed on Jan. 7, 2016. The above application is hereby expressly incorporated by reference, in its entirety, into the present application.

### BACKGROUND OF THE INVENTION

### 1. Field of the Invention

The present invention relates to a laminated film used in a backlight or the like of a liquid crystal display and to a method for manufacturing a laminated film.

### 2. Description of the Related Art

As an image display device that consumes less power and occupies a small space, a liquid crystal display (hereinafter, referred to as LCD as well) is increasingly widely used year after year. Furthermore, in recent years, for the liquid crystal display, a further reduction in power consumption, the enhancement of color reproducibility, and the like have been required as the improvement of LCD performance.

As the reduction in power consumption is required for LCD, in order to increase light use efficiency in a backlight (backlight unit) and enhance color reproducibility, the use of a quantum dot, which emits light by converting the wavelength of incidence rays, in the backlight is suggested.

The quantum dot is in an electronic state of which the movement is restricted in all directions in a three-dimensional space. In a case where a semiconductor nanoparticle is three-dimensionally surrounded by a high-potential barrier, the nanoparticle becomes a quantum dot. The quantum dot exhibits various quantum effects. For example, the quantum dot exhibits “quantum size effect” in which the state density (energy level) of an electron becomes discrete. According to the quantum size effect, by changing the size of the quantum dot, the absorption wavelength or emission wavelength of light can be controlled.

Generally, quantum dots are made into a quantum dot layer by being dispersed in a matrix formed of a resin such as an acrylic resin or an epoxy resin. For example, as a quantum dot film performing wavelength conversion, the quantum layer is used by being disposed between a backlight and a liquid crystal panel.

In a case where excitation light from the backlight is incident on the quantum dot film, the quantum dots are excited and emit fluorescence. At this time, in a case where quantum dots having different emission characteristics are used, light having a narrow half-width such as red light, green light, and blue light is emitted, and hence white light can be realized. Because the fluorescence from the quantum dots has a narrow half-width, by appropriately selecting the wavelength, it is possible to obtain white light with high luminance or to prepare a design so as to obtain excellent color reproducibility.

Incidentally, unfortunately, the quantum dots easily deteriorate due to oxygen or the like, and the emission intensity of the quantum dots deteriorates due to a photo-oxidation reaction. Therefore, in a quantum dot film, a gas barrier film is laminated on both surfaces of a quantum dot layer so as to protect the quantum dot layer.

However, in a case where both surfaces of the quantum dot layer are simply sandwiched between gas barrier films, unfortunately, moisture or oxygen permeates the quantum dot layer from the end face not being covered with the gas barrier film, and hence the quantum dots deteriorate.

Accordingly, a method is suggested in which in addition to both surfaces of a quantum dot layer, the periphery of the quantum dot layer is also sealed with a gas barrier film or the like.

For example, WO2012/102107A describes a composition obtained by dispersing quantum dot phosphors in a cycloolefin (co)polymer at a concentration within a range of 0.0% to 20% by mass, and describes a constitution having a gas barrier layer that coats the entire surface of a resin-molded material in which quantum dots are dispersed. WO2012/102107A also describes that the gas barrier layer is a gas barrier film obtained by forming a silica film or an alumina film on at least one surface of a resin layer.

JP2013-544018A describes a display backlight unit including a remote phosphor film containing an emission quantum dot (QD) aggregate, and describes a constitution in which a QD phosphor material is sandwiched between two gas barrier films, and an inert region having gas barrier properties is located in a region sandwiched between the two gas barrier films at the periphery around the QD phosphor material.

JP2009-283441A describes a light emitting device including a color conversion layer that converts at least a portion of colored light emitted from a light source portion into another colored light and an impermeable sealing sheet that seals the color conversion layer, and describes a constitution including a second adhesive layer provided in the form of a frame along the outer periphery of a phosphor layer, that is, surrounding the planar shape of the phosphor layer, in which the second adhesive layer is formed of an adhesive material having gas barrier properties.

Furthermore, JP2010-61098A describes a quantum dot wavelength converter having a quantum dot layer (wavelength converting portion) and sealing members formed of silicone or the like that seals the quantum dot layer, and describes a constitution in which the quantum dot layer is sandwiched between the sealing members, and the sealing members are bonded to each other on the periphery of the quantum dot layer.

### SUMMARY OF THE INVENTION

The laminated film containing quantum dots used for LCD is a thin film having a thickness of about 50 μm to 350 μm.

Coating the entire surface of such a thin quantum dot layer with a gas barrier film as described in WO2012/102107A is extremely difficult, and doing such a thing has a problem of poor productivity. Furthermore, unfortunately, in a case where the gas barrier film is folded, the barrier layer cracks, and hence the gas barrier properties deteriorate.

In a case where a constitution is adopted in which a protective layer having gas barrier properties is formed in an end face region of a quantum dot layer sandwiched between two gas barrier films as described in JP2013-544018A and JP2009-283441A, a so-called dam filling-type laminated film is prepared by forming a protective layer at the peripheral portion of one gas barrier film, then forming a resin layer in the region surrounded by the protective layer, and then laminating the other gas barrier film on the protective layer and the resin layer. However, in this case, because the entire process is performed by a batch method, the problem of extremely poor productivity arises. Furthermore, because the width of the protective layer increases, the quantum dot layer is not formed on the edge. Accordingly, the area of an effectively usable region decreases, and this leads to the problem of the enlargement of a frame portion.

In the constitution described in JP2010-61098A in which the opening on the edge of two gas barrier films sandwiching the quantum dot layer therebetween is narrowed and sealed, the thickness of the quantum dot layer on the edge decreases. Accordingly, the area of a region, in which the quantum dot layer having a uniform thickness can be effectively used, is too small for the display use, and this leads to the problem of the enlargement of a frame portion. In addition, because a barrier layer having high gas barrier properties is generally hard and brittle, in a case where a gas barrier film having such a barrier layer is suddenly curved, unfortunately, the barrier layer cracks, and the gas barrier properties deteriorate.

The present invention is for solving the aforementioned problems of the related art, and an object thereof is to provide a laminated film having a wavelength conversion layer such as a quantum dot layer, in which the wavelength conversion layer can be inhibited from deteriorating due to the permeation of oxygen or the like from the end face while maintaining the area of an effectively usable region.

In order to achieve the aforementioned object, the inventors of the present invention conducted an intensive study. As a result, the inventors obtained knowledge that the object can be achieved by providing a functional layer laminate having a wavelength conversion layer and a gas barrier film laminated on both main surfaces of the wavelength conversion layer so as to sandwich the wavelength conversion layer, and an end face sealing layer covering a region from a portion of one main surface of the functional layer laminate to a portion of the other main surface including the entirety of end face of the functional layer laminate, in which the end face sealing layer has a build-up portion formed on the main surface of the functional layer laminate, and a width of the build-up portion measured from the end face is equal to or greater than 0.01 mm and equal to or smaller than 8% of a length of the main surface. Based on the knowledge, the inventors have accomplished the present invention.

That is, the present invention provides a laminated film constituted as below.

(1) A laminated film comprising a functional layer laminate having a wavelength conversion layer and a gas barrier film laminated on both main surfaces of the wavelength conversion layer so as to sandwich the wavelength conversion layer, and an end face sealing layer covering a region from a portion of one main surface of the functional layer laminate to a portion of the other main surface including the entirety of end face of the functional layer laminate, in which the end face sealing layer has a build-up portion formed on the main surface of the functional layer laminate, and a width of the build-up portion measured from the end face is equal to or greater than 0.01 mm and equal to or smaller than 8% of a length of the main surface.

(2) The laminated film described in (1), in which a height of the end face sealing layer measured from the main surface in a direction perpendicular to the main surface is greater than 0% of a thickness of the functional layer laminate and equal to or smaller than 20% of the thickness of the functional layer laminate.

(3) The laminated film described in (1) or (2), in which the end face sealing layer is constituted with multiple layers.

(4) The laminated film described in any one of (1) to (3), in which the functional layer laminate has a diffusion layer on at least one of the gas barrier films.

According to the present invention, it is possible to provide a laminated film having a wavelength conversion layer such as a quantum dot layer, in which the wavelength conversion layer can be inhibited from deteriorating due to the permeation of oxygen or the like from the end face.

### BRIEF DESCRIPTION OF THE DRAWINGS

FIG. 1 is a cross-sectional view conceptually showing an example of a laminated film of the present invention.

FIG. 2 is a cross-sectional view conceptually showing an example of a gas barrier film used in the laminated film of the present invention.

FIG. 3 is a cross-sectional view in which an end face sealing layer is enlarged.

FIG. 4A is a conceptual view for illustrating a method for manufacturing the laminated film of the present invention.

FIG. 4B is a conceptual view for illustrating the method for manufacturing the laminated film of the present invention.

FIG. 4C is a conceptual view for illustrating the method for manufacturing the laminated film of the present invention.

### DESCRIPTION OF THE PREFERRED EMBODIMENTS

Hereinafter, the laminated film of the present invention will be specifically described based on preferred embodiments shown in the attached drawings.

The following constituents will be described based on typical embodiments of the present invention in some cases, but the present invention is not limited to the embodiments.

In the present specification, a range of numerical values described using “to” means a range including the numerical values listed before and after “to” as a lower limit and an upper limit respectively.

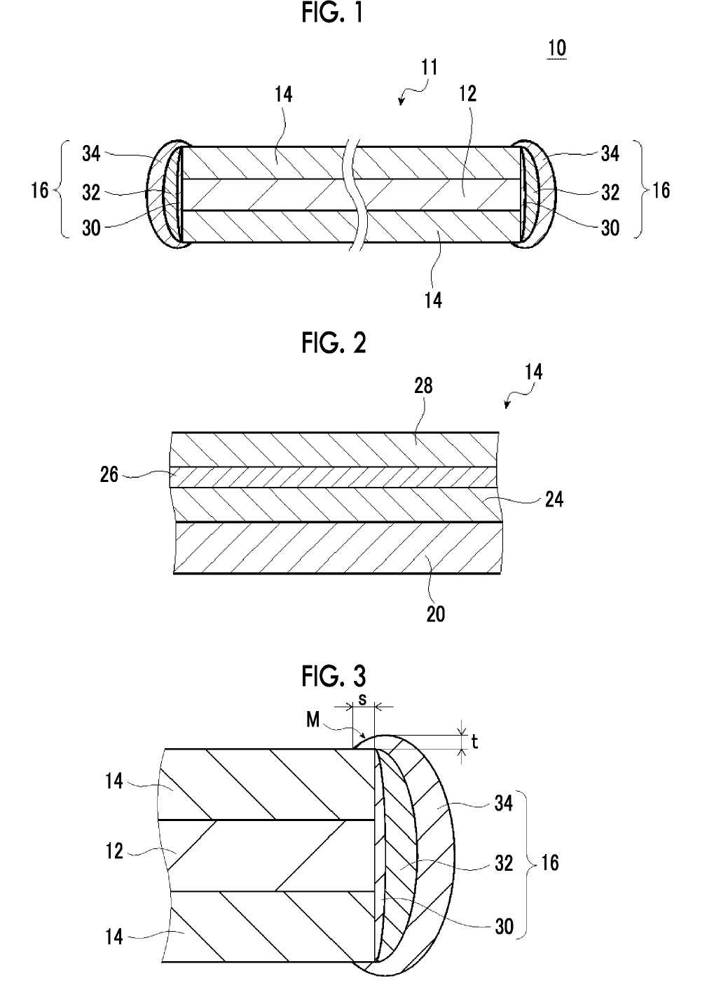

FIG. 1 is a cross-sectional view conceptually showing an example of a laminated film of the present invention.

A laminated film 10 shown in FIG. 1 has a wavelength conversion layer 12, two gas barrier films 14, and an end face sealing layer 16. As shown in FIG. 1, the laminated film 10 has a constitution in which the gas barrier film 14 is laminated on both surfaces (both main surfaces) of the sheet-like wavelength conversion layer 12, and the entirety of end faces of a functional layer laminate 11, in which the wavelength conversion layer 12 is sandwiched between the gas barrier films 14, is covered with the end face sealing layer 16.

In the example shown in the drawing, the end face sealing layer 16 is constituted with three layers including a first layer 30, a second layer 32, and a third layer 34 that are laminated in this order from the end face side of the functional layer laminate 11.

The end face sealing layer 16 covers a region from a portion of one main surface of the functional layer laminate 11 to a portion of the other main surface including the entirety of the end face of the functional layer laminate 11. Provided that a portion of the end face sealing layer 16 that is formed on the main surface of the functional layer laminate 11 is named a build-up portion M, a width of the build-up portion M from the end face is equal to or greater than 0.01 mm and equal to or smaller than 8% of the length of the main surface.

The wavelength conversion layer 12 is a layer for expressing a wavelength conversion function, and is a sheet-like substance having a quadrangular planar shape, for example.

As the wavelength conversion layer 12, it is possible to use various layers such as a quantum dot layer expressing a function of emitting light by converting the wavelength of light incident thereon.

Particularly, by having the end face sealing layer 16, the wavelength conversion layer 12 enables the characteristics of the laminated film of the present invention, such as being able to prevent an optically functional material from deteriorating due to oxygen, water, or the like permeating from the end face, to be sufficiently exhibited. Therefore, a quantum dot layer, which is used in LCD or the like assumed to be used in various environments such as an in-vehicle environment with a high temperature and a high humidity and in which the deterioration of quantum dots resulting from oxygen becomes a big issue, can be suitably used as the wavelength conversion layer 12.

For example, the quantum dot layer is a layer obtained by dispersing a number of quantum dots in a matrix such as a resin, and has a function of emitting light by converting the wavelength of light incident on the wavelength conversion layer 12.

For instance, in a case where blue light emitted from a backlight not shown in the drawing is incident on wavelength conversion layer 12, by the effect of the quantum dots contained in the wavelength conversion layer 12, the wavelength conversion layer 12 performs wavelength conversion, such that at least a portion of the blue light becomes red light or green light, and then emits the light.

Herein, the blue light refers to light having an emission wavelength centered at a wavelength range of 400 to 500 nm, the green light refers to light having an emission wavelength centered at a wavelength range of 500 to 600 nm, and the red light refers to light having an emission wavelength centered at a wavelength range longer than 600 nm and equal to or shorter than 680 nm.

The wavelength conversion function that the quantum dot layer expresses is not limited to the constitution in which the wavelength conversion is performed to change the blue light into the red light or the green light, and only at least a portion of incidence rays needs to be converted into light having a different wavelength.

The quantum dot emits fluorescence by being excited with at least excitation light incident thereon.

The type of the quantum dot contained in the quantum dot layer is not particularly limited, and according to the required wavelength conversion performance or the like, various known quantum dots may be appropriately selected.

Regarding the quantum dot, for example, paragraphs “0060” to “0066” in JP2012-169271A can be referred to, but the present invention is not limited to those described in the paragraphs. As the quantum dot, commercial products can be used without restriction. Generally, the emission wavelength of the quantum dot can be adjusted by the composition or size of the particles.

Although it is preferable that quantum dots are evenly dispersed in a matrix, the quantum dots may be unevenly dispersed in the matrix.

Furthermore, one kind of quantum dot may be used singly, or two or more kinds of quantum dots may be used in combination.

In a case where two or more kinds of quantum dots are used in combination, quantum dots that emit light having different wavelengths may be used.

Specifically, known quantum dots include a quantum dot (A) having an emission wavelength centered at a wavelength range of 600 to 680 nm, a quantum dot (B) having an emission wavelength centered at a wavelength range of 500 to 600 nm, and a quantum dot (C) having a emission wavelength centered at a wavelength range of 400 to 500 nm. The quantum dot (A) emits red light by being excited with excitation light, the quantum dot (B) emits green light, and the quantum dot (C) emits blue light. For example, in a case where blue light is caused to incident as excitation light on a quantum dot-containing laminate containing the quantum dot (A) and the quantum dot (B), by the red light emitted from the quantum dot (A), the green light emitted from the quantum dot (B), and the blue light transmitted through the quantum dot layer, white light can be realized. Furthermore, in a case where ultraviolet light is caused to incident as excitation light on the quantum dot layer containing the quantum dots (A), (B), and (C), by the red light emitted from the quantum dot (A), the green light emitted from the quantum dot (B), and the blue light emitted from the quantum dot (C), white light can be realized.

As quantum dots, so-called quantum rods which have a rod shape and emit polarized light with directionality or tetrapod-type quantum dots may be used.

The type of the matrix of the quantum dot layer is not particularly limited, and various resins used in known quantum dot layers can be used.

Examples of the matrix include a polyester-based resin (for example, polyethylene terephthalate and polyethylene naphthalate), a (meth)acrylic resin, a polyvinyl chloride-based resin, a polyvinylidene chloride-based resin, and the like. Alternatively, as the matrix, it is possible to use a curable compound having a polymerizable group. The type of the polymerizable group is not limited, but the polymerizable group is preferably a (meth)acrylate group, a vinyl group, or an epoxy group, more preferably a (meth)acrylate group, and particularly preferably an acrylate group. In a polymerizable monomer having two or more polymerizable groups, the polymerizable groups may be the same as or different from each other.

Specifically, for example, a resin containing a first polymerizable compound and a second polymerizable compound described below can be used as a matrix.

The first polymerizable compound is preferably one or more compounds selected from the group consisting of a (meth)acrylate monomer having two or more functional groups and a monomer having two or more functional groups selected from the group consisting of an epoxy group and an oxetanyl group.

Examples of the (meth)acrylate monomer having two or more functional groups preferably include difunctional (meth)acrylate monomers such as neopentyl glycol di(meth)acrylate, 1,9-nonanediol di(meth)acrylate, tripropylene glycol di(meth)acrylate, ethylene glycol di(meth)acrylate, tetraethylene glycol di(meth)acrylate, hydroxypivalic acid neopentyl glycol di(meth)acrylate, polyethylene glycol di(meth)acrylate, dicyclopentenyl (meth)acrylate, dicyclopentenyloxyethyl (meth)acrylate, and dicyclopentanyl di(meth)acrylate.

Examples of the (meth)acrylate monomer having two or more functional groups preferably include (meth)acrylate monomers having three or more functional groups such as ECH-modified glycerol tri(meth)acrylate, EO-modified glycerol tri(meth)acrylate, PO-modified glycerol tri(meth)acrylate, pentaerythritol triacrylate, pentaerythritol tetraacrylate, EO-modified phosphoric acid triacrylate, trimethylolpropane tri(meth)acrylate, caprolactone-modified trimethylolpropane tri(meth)acrylate, EO-modified trimethylolpropane tri(meth)acrylate, PO-modified trimethylolpropane tri(meth)acrylate, tris(acryloxyethyl)isocyanurate, dipentaerythritol hexa(meth)acrylate, dipentaerythritol penta(meth)acrylate, caprolactone-modified dipentaerythritol hexa(meth)acrylate, dipentaerythritol hydroxypenta(meth)acrylate, alkyl-modified dipentaerythritol penta(meth)acrylate, dipentaerythritol poly(meth)acrylate, alkyl-modified dipentaerythritol tri(meth)acrylate, ditrimethylolpropane tetra(meth)acrylate, pentaerythritol ethoxy tetra(meth)acrylate, and pentaerythritol tetra(meth)acrylate.

As the monomer having two or more functional groups selected from the group consisting of an epoxy group and an oxetanyl group, an aliphatic cyclic epoxy compound, bisphenol A diglycidyl ether, bisphenol F diglycidyl ether, bisphenol S diglycidyl ether, brominated bisphenol A diglycidyl ether, brominated bisphenol F diglycidyl ether, brominated bisphenol S diglycidyl ether, hydrogenated bisphenol A diglycidyl ether, hydrogenated bisphenol F diglycidyl ether, hydrogenated bisphenol S diglycidyl ether, 1,4-butanediol diglycidyl ether, 1,6-hexanediol diglycidyl ether, glycerin triglycidyl ether, trimethylolpropane triglycidyl ether, polyethylene glycol diglycidyl ether, polypropylene glycol diglycidyl ethers; polyglycidyl ethers of polyether polyol obtained by adding one kind or two or more kinds of alkylene oxide to an aliphatic polyhydric alcohol such as ethylene glycol, propylene glycol, or glycerin; diglycidyl esters of aliphatic long-chain dibasic acid; glycidyl esters of higher fatty acids; a compound containing epoxycycloalkane, and the like are suitably used.

Examples of commercial products that can be suitably used as the monomer having two or more functional groups selected from the group consisting of an epoxy group and an oxetanyl group include CELLOXIDE 2021P and CELLOXIDE 8000 manufactured by Daicel Corporation, 4-vinylcyclohexene dioxide manufactured by Sigma-Aldrich Co. LLC., and the like. One kind of these monomers can be used singly, or two or more kinds of these monomers can be used in combination.

The monomer having two or more functional groups selected from the group consisting of an epoxy group and an oxetanyl group may be prepared by any method. For example, the monomer can be synthesized with reference to the documents such as “Experimental Chemistry Course 20, Organic Synthesis I”, pp. 213˜, 1992, MARUZEN SHUPPAN K. K, “The chemistry of heterocyclic compounds-Small Ring Heterocycles, part 3 Oxiranes”, Ed. By Alfred Hasfner, John & Wiley and sons, An Interscience Publication, New York, 1985, “Adhesion”, Yoshimura, Vol. 29, No. 12, 32, 1985, “Adhesion”, Yoshimura, Vol. 30, No. 5, 42, 1986, “Adhesion”, Yoshimura, Vol. 30, No. 7, 42, 1986, JP1999-100378A (JP-H11-100378A), JP2906245B, and JP2926262B.

The second polymerizable compound has a functional group which has hydrogen bonding properties in a molecule and a polymerizable group which can cause a polymerization reaction with the first polymerizable compound.

Examples of the functional group having hydrogen bonding properties include a urethane group, a urea group, a hydroxyl group, and the like.

In a case where the first polymerizable compound is a (meth)acrylate monomer having two or more functional groups, the polymerizable group which can cause a polymerization reaction with the first polymerizable compound may be a (meth)acryloyl group, for example. In a case where the first polymerizable compound is a monomer having two or more functional groups selected from the group consisting of an epoxy group and an oxetanyl group, the polymerizable group which can cause a polymerization reaction may be an epoxy group or an oxetanyl group.

Examples of the (meth)acrylate monomer containing a urethane group include monomers and oligomers obtained by reacting diisocyanate such as TDI, MDI, HDI, IPDI, and HMDI with polyol such as poly(propyleneoxide)diol, poly(tetramethyleneoxide)diol, ethoxylated bisphenol A, ethoxylated bisphenol S spiroglycol, caprolactone-modified diol, and carbonate diol and hydroxyacrylate such as 2-hydroxyethyl (meth)acrylate, 2-hydroxypropyl (meth)acrylate, glycidol di(meth)acrylate, and pentaerythritol triacrylate, and polyfunctional urethane monomers described in JP2002-265650A, JP2002-355936A, JP2002-067238A, and the like. Specifically, examples thereof include an adduct of TDI and hydroxyethyl acrylate, an adduct of IPDI and hydroxyethyl acrylate, an adduct of HDI and pentaerythritol triacrylate (PETA), a compound obtained by making an adduct of TDI and PETA and reacting the remaining isocyanate with dodecyloxyhydroxypropyl acrylate, an adduct of 6,6 nylon and TDI, an adduct of pentaerythritol, TDI, and hydroxyethyl acrylate, and the like, but the present invention is not limited to these.

Examples of commercial products that can be suitably used as the (meth)acrylate monomer containing a urethane group include AH-600, AT-600, UA-306H, UA-306T, UA-3061, UA-510H, UF-8001G, and DAUA-167 manufactured by KYOEISHA CHEMICAL Co., LTD., UA-160TM manufactured by SHIN-NAKAMURA CHEMICAL CO., LTD., UV-4108F and UV-4117F manufactured by OSAKA ORGANIC CHEMICAL INDUSTRY LTD., and the like. One kind of these monomers can be used singly, or two or more kinds of these monomers can be used in combination.

Examples of the (meth)acrylate monomer containing a hydroxyl group include a compound synthesized by causing a reaction between a compound having an epoxy group and (meth)acrylic acid. Typical examples of the monomer are classified into, depending on the compound having an epoxy group, a bisphenol A type, a bisphenol S type, a bisphenol F type, an epoxidized oil type, a phenol novolac type, and alicyclic type. Specific examples of the monomer include (meth)acrylate obtained by reacting an adduct of bisphenol A and epichlorohydrin with (meth)acrylic acid, (meth)acrylate obtained by reacting phenol novolac with epichlorohydrin and then reacting the product with (meth)acrylic acid, (meth)acrylate obtained by reacting an adduct of bisphenol S and epichlorohydrin with (meth)acrylic acid, (meth)acrylate obtained by reacting epoxidized soybean oil with (meth)acrylic acid, and the like. Examples of the (meth)acrylate monomer having a hydroxyl group also include a (meth)acrylate monomer having a carboxyl group or a phosphoric acid group on the terminal, and the like, but the present invention is not limited thereto.

Examples of commercial products that can be suitably used as the second polymerizable compound containing a hydroxyl group include epoxy ester, M-600A, 40EM, 70PA, 200PA, 80MFA, 3002M, 3002A, 3000MK, and 3000A manufactured by KYOEISHA CHEMICAL Co., LTD., 4-hydroxybutyl acrylate manufactured by Nippon Kasei Chemical Co., Ltd, monofunctional acrylate A-SA and monofunctional methacrylate SA manufactured by SHIN-NAKAMURA CHEMICAL CO., LTD., monofunctional acrylate 3-carboxyethyl acrylate manufactured by DAICEL-ALLNEX LTD., JPA-514 manufactured by JOHOKU CHEMICAL CO., LTD, and the like. One kind of these can be used singly, or two or more kinds of these can be used in combination.

A mass ratio of first polymerizable compound:second polymerizable compound may be 10:90 to 99:1, and is preferably 10:90 to 90:10. It is preferable that the content of the first polymerizable compound is greater than the content of the second polymerizable compound. Specifically, (content of first polymerizable compound)/(content of second polymerizable compound) is preferably 2 to 10.

In a case where the resin containing the first polymerizable compound and the second polymerizable compound is used as a matrix, it is preferable that the matrix further contains a monofunctional (meth)acrylate monomer. Examples of the monofunctional (meth)acrylate monomer include acrylic acid, methacrylic acid, and derivatives of these, and more specifically include a monomer having one polymerizable unsaturated bond ((meth)acryloyl group) of (meth)acrylic acid in a molecule. Specific examples of the monomer include the following compounds, but the present invention is not limited thereto.

Examples of the monomer include alkyl (meth)acrylate containing an alkyl group having 1 to 30 carbon atoms such as methyl (meth)acrylate, n-butyl (meth)acrylate, isobutyl (meth)acrylate, 2-ethylhexyl (meth)acrylate, isononyl (meth)acrylate, n-octyl (meth)acrylate, lauryl (meth)acrylate, and stearyl (meth)acrylate; aralkyl (meth)acrylate containing an aralkyl group having 7 to 20 carbon atoms, such as benzyl (meth)acrylate; alkoxyalkyl (meth)acrylate containing an alkoxyalkyl group having 2 to 30 carbon atoms, such as butoxyethyl (meth)acrylate; aminoalkyl (meth)acrylate containing a (monoalkyl or dialkyl) aminoalkyl group having 1 to 20 carbon atoms in total, such as N,N-dimethylaminoethyl (meth)acrylate; (meth)acrylate of polyalkylene glycol alkyl ether containing an alkylene chain having 1 to 10 carbon atoms and terminal alkyl ether having 1 to 10 carbon atoms, such as (meth)acrylate of diethylene glycol ethyl ether. (meth)acrylate of triethylene glycol butyl ether, (meth)acrylate of tetraethylene glycol monomethyl ether, (meth)acrylate of hexaethylene glycol monomethyl ether, monomethyl ether (meth)acrylate of octaethylene glycol, monomethyl ether (meth)acrylate of nonaethylene glycol, monomethyl ether (meth)acrylate of dipropylene glycol, monomethyl ether (meth)acrylate of heptapropylene glycol, and monoethyl ether (meth)acrylate of tetraethylene glycol; (meth)acrylate of polyalkylene glycol aryl ether containing an alkylene chain having 1 to 30 carbon atoms and terminal aryl ether having 6 to 20 carbon atoms, such as (meth)acrylate of hexaethylene glycol phenyl ether, (meth)acrylate having an alicyclic structure containing 4 to 30 carbon atoms in total, such as cyclohexyl (meth)acrylate, dicyclopentanyl (meth)acrylate, isobornyl (meth)acrylate, and methylene oxide-added cyclodecatriene (meth)acrylate; fluorinated alkyl (meth)acrylate having 4 to 30 carbon atoms in total such as heptadecafluorodecyl (meth)acrylate; (meth)acrylate having a hydroxyl group such as 2-hydroxyethyl (meth)acrylate, 3-hydroxypropyl (meth)acrylate, 4-hydroxybutyl (meth)acrylate, mono(meth)acrylate of triethylene glycol, tetraethylene glycol mono(meth)acrylate, hexaethylene glycol mono(meth)acrylate, octapropylene glycol mono(meth)acrylate, and mono- or di(meth)acrylate of glycerol; (meth)acrylate having a glycidyl group such as glycidyl (meth)acrylate; polyethylene glycol mono(meth)acrylate having an alkylene chain containing 1 to 30 carbon atoms, such as tetraethylene glycol mono(meth)acrylate, hexaethylene glycol mono(meth)acrylate, and octapropylene glycol mono(meth)acrylate; (meth)acrylamide such as (meth)acrylamide, N,N-dimethyl (meth)acrylamide, N-isopropyl (meth)acrylamide, 2-hydroxyethyl (meth)acrylamide, and acryloylmorpholine; and the like.

The content of the monofunctional (meth)acrylate monomer with respect to the total mass (100 parts by mass) of the first polymerizable compound and the second polymerizable compound is preferably 1 to 300 parts by mass, and more preferably 50 to 150 parts by mass.

Furthermore, it is preferable that the resin contains a compound having a long-chain alkyl group containing 4 to 30 carbon atoms. Specifically, it is preferable that at least any one of the first polymerizable compound, the second polymerizable compound, or the monofunctional (meth)acrylate monomer has a long-chain alkyl group having 4 to 30 carbon atoms. It is preferable that long-chain alkyl group is a long-chain alkyl group having 12 to 22 carbon atoms, because then the dispersibility of the quantum dots is improved. The further the dispersibility of the quantum dots is improved, the further the amount of light that goes straight to an emission surface from a light conversion layer increases. Accordingly, the improvement of the dispersibility of the quantum dots is effective for improving front luminance and front contrast.

Specifically, as the monofunctional (meth)acrylate monomer having a long-chain alkyl group containing 4 to 30 carbon atoms, butyl (meth)acrylate, octyl (meth)acrylate, lauryl (meth)acrylate, oleyl (meth)acrylate, stearyl (meth)acrylate, behenyl (meth)acrylate, butyl (meth)acrylamide, octyl (meth)acrylamide, lauryl (meth)acrylamide, oleyl (meth)acrylamide, stearyl (meth)acrylamide, behenyl (meth)acrylamide, and the like are preferable. Among these, lauryl (meth)acrylate, oleyl (meth)acrylate, and stearyl (meth)acrylate are particularly preferable.

Furthermore, the resin which becomes a matrix may contain a compound having a fluorine atom such as trifluoroethyl (meth)acrylate, pentafluoroethyl (meth)acrylate, (perfluorobutyl)ethyl (meth)acrylate, perfluorobutyl-hydroxypropyl (meth)acrylate, (perfluorohexyl)ethyl (meth)acrylate, octafluoropentyl (meth)acrylate, perfluorooctyl ethyl (meth)acrylate, and tetrafluoropropyl (meth)acrylate. In a case where the resin contains these compounds, the coating properties can be further improved.

The total amount of the resin, which becomes a matrix, in the quantum dot layer is not limited. The total amount of the resin with respect to a total of 100 parts by mass of the quantum dot layer is preferably 90 to 99.9 parts by mass, and more preferably 92 to 99 parts by mass.

The thickness of the quantum dot layer may be appropriately set according to the thickness of the laminated film 10 or the like. According to the examination performed by the inventors of the present invention, in view of handleability and emission characteristics, the thickness of the quantum dot layer is preferably 5 to 200 μm, and more preferably 10 to 150 μm.

The aforementioned thickness means an average thickness which can be determined by measuring thicknesses of ten or more random spots in the quantum dot layer and calculating an arithmetic mean thereof.

The method for forming the quantum dot layer is not limited, and the quantum dot layer may be formed by a known method. For example, the quantum dot layer can be formed by preparing a composition (paint-coating composition) by means of mixing quantum dots, a resin which becomes a matrix, and a solvent together, coating the gas barrier film 14 with the composition, and curing the composition.

If necessary, a polymerization initiator, a silane coupling agent, and the like may be added to the composition that becomes the quantum dot layer.

In the laminated film 10, on both surfaces of the wavelength conversion layer 12 such as a quantum dot layer, the gas barrier film 14 is laminated such that the entirety of the main surfaces of the wavelength conversion layer 12 is covered. That is, the laminated film 10 has a constitution in which the wavelength conversion layer 12 is sandwiched between the gas barrier films 14.

The gas barrier films 14 provided on both surfaces of the wavelength conversion layer 12 may be the same as or different from each other.

The gas barrier film 14 is a layer for inhibiting oxygen or the like from permeating the wavelength conversion layer 12 such as a quantum dot layer from the main surface. Accordingly, it is preferable that the gas barrier film 14 has high gas barrier properties. Specifically, the oxygen permeability of the gas barrier film 14 is preferably equal to or lower than 0.1 cc/(m²·day·atm), more preferably equal to or lower than 0.01 cc/(m²·day·atm), and particularly preferably equal to or lower than 0.001 cc/(m²·day·atm).

In a case where the oxygen permeability of the gas barrier film 14 is equal to or lower than 0.1 cc/(m²·day·atm), it is possible to inhibit the wavelength conversion layer 12 from deteriorating due to oxygen or the like permeating from the main surface of the wavelength conversion layer 12 and to obtain a laminated film such as a quantum dot film having long service life.

In the present invention, the oxygen permeability of the gas barrier film 14, the end face sealing layer 16, or the like may be measured based on known methods or the examples which will be described later.

Furthermore, the unit cc/(m²·day·atm) of oxygen permeability is expressed as 9.87 mL/(m²·day·MPa) in terms of the SI unit.

As the gas barrier film 14, various materials such as a layer (film) formed of a known material exhibiting gas barrier properties and a known gas barrier film can be used, as long as the materials have sufficient optical characteristics in view of transparency or the like and yield intended gas barrier properties (oxygen barrier properties).

As a preferred gas barrier film 14, a gas barrier film can be exemplified which has an organic and inorganic laminated structure obtained by alternately laminating an organic layer and an inorganic layer on a support (on one surface or both surfaces of a support).

FIG. 2 conceptually shows a cross-section of an example of the gas barrier film 14.

The gas barrier film 14 shown in FIG. 2 is a gas barrier film having an organic layer 24 on a support 20, an inorganic layer 26 on the organic layer 24, and an organic layer 28 on the inorganic layer 26.

In the gas barrier film 14, gas barrier properties are expressed mainly by the inorganic layer 26. The organic layer 24 as an underlayer of the inorganic layer 26 is an underlayer for appropriately forming the inorganic layer 26. The organic layer 28 as the uppermost layer functions as a protective layer for the inorganic layer 26.

In the laminated film of the present invention, the gas barrier film 14 having an organic and inorganic laminated structure is not limited to the example shown in FIG. 2.

For example, the gas barrier film 14 may not have the organic layer 28 as the uppermost layer that functions as a protective layer.

Furthermore, although the gas barrier film 14 in the example shown in FIG. 2 has only one combination of the inorganic layer and the organic layer as a base, the gas barrier film 14 may have two or more combinations of the inorganic layer and the organic layer as a base. Generally, the larger the number of combinations of the inorganic layer and the organic layer as a base, the higher the gas barrier properties.

In addition, a constitution may be adopted in which an inorganic layer is formed on the support 20, and one or more combinations of an inorganic layer and an organic layer as a base are provided on the aforementioned inorganic layer.

As the support 20 of the gas barrier film 14, it is possible to use various materials that are used as a support in known gas barrier films.

Among these, films formed of various resin materials (polymer materials) are suitably used, because these films make it easy to obtain a thin or lightweight support and are suitable for making a flexible support.

Specifically, plastic films formed of polyethylene (PE), polyethylene naphthalate (PEN), polyamide (PA), polyethylene terephthalate (PET), polyvinyl chloride (PVC), polyvinyl alcohol (PVA), polyacrylonitrile (PAN), polyimide (PI), transparent polyimide, a polymethyl methacrylate resin (PMMA), polycarbonate (PC), polyacrylate, polymethacrylate, polypropylene (PP), polystyrene (PS), ABS, a cycloolefin.copolymer (COC), a cycloolefin polymer (COP), and triacetyl cellulose (TAC) can be suitably exemplified.

The thickness of the support 20 may be appropriately set according to the thickness, size, and the like of the laminated film 10. According to the examination performed by the inventors of the present invention, the thickness of the support 20 is preferably about 10 μm to 100 μm. In a case where the thickness of the support 20 is within the above range, in view of making a lightweight or thin support, preferable results are obtained.

To the surface of the plastic film of which the support 20 is formed, the functions of preventing reflection, controlling phase difference, improving light extraction efficiency, and the like may be imparted.

In the gas barrier film 14, the organic layer 24 is formed on a surface of the support 20.

The organic layer 24 which is formed on a surface of the support 20, that is, the organic layer 24 which becomes the underlayer of the inorganic layer 26 becomes the underlayer of the inorganic layer 26 that mainly exhibits gas barrier properties in the gas barrier film 14.

In a case where the gas barrier film 14 has the organic layer 24, the surface asperities of the support 20, foreign substances having adhered to the surface of the support 20, and the like are concealed, and hence a deposition surface for the inorganic layer 26 can be in a state suitable for forming the inorganic layer 26. Accordingly, it is possible to form an appropriate inorganic layer 26 without voids on the entire surface of the substrate, by removing regions, on which an inorganic compound that becomes the inorganic layer 26 is not easily deposited as a film, such as surface asperities or shadows of foreign substances on the support 20. As a result, a gas barrier film 14 having an oxygen permeability of equal to or lower than 0.1 cc/(m²·day·atm) can be stably formed.

In the gas barrier film 14, as the material for forming the organic layer 24, various known organic compounds can be used without restriction.

Specifically, thermoplastic resins such as polyester, a (meth)acrylic resin, a methacrylic acid-maleic acid copolymer, polystyrene, a transparent fluorine resin, polyimide, fluorinated polyimide, polyamide, polyamide imide, polyether imide, cellulose acylate, polyurethane, polyether ether ketone, polycarbonate, alicyclic polyolefin, polyarylate, polyether sulfone, polysulfone, fluorene ring-modified polycarbonate, alicyclic ring-modified polycarbonate, fluorene ring-modified polyester, and an acryl compound, polysiloxane, and films of other organic silicon compounds can be suitably exemplified. A plurality of these materials may be used in combination.

Among these, in view of excellent glass transition temperature or hardness, an organic layer 24 is suitable which is constituted with a polymer of a radically curable compound and/or a cationically curable compound having an ether group as a functional group.

Particularly, an acrylic resin or a methacrylic resin, which contains a polymer of a monomer or an oligomer of acrylate and/or methacrylate as a main component, can be suitably exemplified as the organic layer 24, because such a resin has low refractive index, high transparency, excellent optical characteristics, and the like.

Especially, an acrylic resin or a methacrylic resin can be suitably exemplified which contains, as a main component, a polymer of a monomer or an oligomer of acrylate and/or methacrylate having two or more functional groups, particularly, three or more functional groups, such as dipropylene glycol di(meth)acrylate (DPGDA), trimethylolpropane tri(meth)acrylate (TMPTA), or dipentaerythritol hexa(meth)acrylate (DPHA). Furthermore, it is preferable to use a plurality of acrylic resins or methacrylic resins described above.

The thickness of the organic layer 24 may be appropriately set according to the material for forming the organic layer 24 or the support 20. According to the examination performed by the inventors of the present invention, the thickness of the organic layer 24 is preferably 0.5 to 5 μm, and more preferably 1 to 3 μm.

In a case where the thickness of the organic layer 24 is equal to or greater than 0.5 μm, the surface of the organic layer 24, that is, the deposition surface for the inorganic layer 26 can be flattened by concealing the surface asperities of the support 20 or the foreign substances having adhered to the surface of the support 20. In a case where the thickness of the organic layer 24 is equal to or smaller than 5 μm, it is possible to suitably inhibit the occurrence of problems such as cracking of the organic layer 24 caused in a case where the organic layer 24 is too thick and curling caused by the gas barrier film 14.

In a case where the gas barrier film has a plurality of organic layers, such as a case where the gas barrier film has a plurality of combinations of an inorganic layer and an organic layer as a base, the organic layers may have the same thickness or different thicknesses.

The organic layer 24 may be formed by a known method such as a coating method or a flash vapor deposition method.

In order to improve the adhesiveness between the organic layer 24 and the inorganic layer 26 that becomes the underlayer of the organic layer 24, it is preferable that the organic layer 24 (composition that becomes the organic layer 24) contains a silane coupling agent.

In a case where the gas barrier film has a plurality of organic layers 24, such as a case where the gas barrier film has a plurality of combinations of an inorganic layer and an organic layer as a base including the organic layer 28 which will be described later, the organic layers may be formed of the same material or different materials. However, in view of productivity and the like, it is preferable that all the organic layers are formed of the same material.

On the organic layer 24, the inorganic layer 26 is formed as the base of the organic layer 24.

The inorganic layer 26 is a film containing an inorganic compound as a main component and mainly exhibits gas barrier properties in the gas barrier film 14.

As the inorganic layer 26, various films can be used which exhibit gas barrier properties and are formed of an inorganic compound such as an oxide, a nitride, or an oxynitride.

Specifically, films formed of inorganic compounds including a metal oxide such as aluminum oxide, magnesium oxide, tantalum oxide, zirconium oxide, titanium oxide, and indium tin oxide (ITO); a metal nitride such as aluminum nitride; a metal carbide such as aluminum carbide; an oxide of silicon such as silicon oxide, silicon oxynitride, silicon oxycarbide, and silicon oxynitrocarbide; a nitride of silicon such as silicon nitride and silicon nitrocarbide; a carbide of silicon such as silicon carbide; hydroxides of these; a mixture of two or more kinds of these; and hydrogenous substances of these can be suitably exemplified.

Particularly, films formed of a silicon compound such as a nitride of silicon, an oxynitride of silicon, and an oxide of silicon can be suitably exemplified, because these films have high transparency and can exhibit excellent gas barrier properties. Among these, a film formed of silicon nitride can be particularly suitably exemplified because this film exhibits better gas barrier properties and has high transparency.

The thickness of the inorganic layer 26 may be appropriately determined according to the material for forming the inorganic layer 26, such that intended gas barrier properties can be exhibited. According to the examination performed by the inventors of the present invention, the thickness of the inorganic layer 26 is preferably 10 to 200 nm, more preferably 10 to 100 nm, and particularly preferably 15 to 75 nm.

In a case where the thickness of the inorganic layer 26 is equal to or greater than 10 nm, an inorganic layer 26 stably demonstrating a sufficient gas barrier performance can be formed. Generally, in a case where the inorganic layer 26 is brittle and too thick, the inorganic layer 26 is likely to experience cracking, fissuring, peeling and the like. However, in a case where the thickness of the inorganic layer 26 is equal to or smaller than 200 nm, the occurrence of cracks can be prevented.

In a case where the gas barrier film has a plurality of inorganic layers 26, the inorganic layers 26 may have the same thickness or different thicknesses.

The inorganic layer 26 may be formed by a known method according to the material forming the inorganic layer 26. Specifically, plasma CVD such as capacitively coupled plasma (CCP)-chemical vapor deposition (CVD) or inductively coupled plasma (ICP)-CVD, sputtering such as magnetron sputtering or reactive sputtering, and a vapor-phase deposition method such as vacuum vapor deposition can be suitably exemplified.

In a case where the gas barrier film has a plurality of inorganic layers, the inorganic layers may be formed of the same material or different materials. However, in view of productivity and the like, it is preferable that all the inorganic layers are formed of the same material.

The organic layer 28 is provided on the inorganic layer 26.

As described above, the organic layer 28 is a layer functioning as a protective layer for the inorganic layer 26. In a case where the laminated film has the organic layer 28 as the uppermost layer, the damage of the inorganic layer 26 exhibiting gas barrier properties can be prevented, and hence the gas barrier film 14 can stably exhibit intended gas barrier properties. Furthermore, in a case where the laminated film has the organic layer 28, it is also possible to improve the adhesiveness between the wavelength conversion layer 12, which is obtained by dispersing quantum dots and the like in a resin that becomes a matrix, and the gas barrier film 14.

The organic layer 28 is basically the same as the aforementioned organic layer 24. In addition to this, as the organic layer 28, it is possible to suitably use an organic layer formed of a graft copolymer which contains an acryl polymer as a main chain and at least either an acryloyl group-terminated urethane polymer or an acryloyl group-terminated urethane oligomer as a side chain and has a molecular weight of 10,000 to 3,000,000 and has an acryl equivalent of equal to or greater than 500 g/mol.

The thickness of the gas barrier film 14 may be appropriately set according to the thickness of the laminated film 10, the size of the laminated film 10, and the like.

According to the examination performed by the inventors of the present invention, the thickness of the gas barrier film 14 is preferably 5 to 100 μm, more preferably 10 to 70 μm, and particularly preferably 15 to 55 μm.

In a case where the thickness of the gas barrier film 14 is equal to or smaller than 100 μm, it is possible to prevent the gas barrier film 14, that is, the laminated film 10 from becoming unnecessarily thick. Furthermore, it is preferable that the thickness of the gas barrier film 14 is equal to or greater than 5 μm, because then the thickness of the wavelength conversion layer 12 can be made uniform at the time of forming the wavelength conversion layer 12 between two gas barrier films 14.

In the example shown in the drawing, the functional layer laminate 11 is constituted with two gas barrier films 14 and the wavelength conversion layer 12. However, layers for obtaining various functions such as a diffusion layer, an anti-Newton ring layer, a protective layer, and an adhesive layer may also be laminated.

Furthermore, the size and shape of the functional layer laminate 11 in the surface direction are not limited.

As described above, the laminated film 10 has a constitution in which the gas barrier film 14 is laminated on both surfaces of the wavelength conversion layer 12, and the entirety of the end faces of the functional layer laminate 11 including the wavelength conversion layer 12 and the gas barrier film 14 is sealed with the end face sealing layer 16.

Herein, as shown in FIG. 3, in the laminated film 10 of the present invention, the end face sealing layer 16 covers a region from a portion of one main surface of the functional layer laminate 11 to a portion of the other main surface including the entirety of the end face of the functional layer laminate 11. Furthermore, provided that a portion of the end face sealing layer 16 that is formed on the main surface of the functional layer laminate 11 is named a build-up portion M, a width s of the build-up portion M from the end face is equal to or greater than 0.01 mm and equal to or smaller than 8% of the length of the main surface.

As described above, in the related art, as a constitution for preventing oxygen or moisture from permeating a wavelength conversion layer such as a quantum dot layer, a constitution in which the entire surface of the wavelength conversion layer is coated with a gas barrier film, a dam-filling method in which both surfaces of the wavelength conversion layer are sandwiched between gas barrier films and the end face region is sealed with a resin layer, a constitution in which the opening of the edge of two gas barrier films sandwiching the wavelength conversion layer therebetween is narrowed and sealed, and the like have been examined.

However, with these constitutions, unfortunately, sufficient gas barrier properties cannot be secured, the frame portion is enlarged, or the productivity is poor.

In contrast, regarding a laminated film formed by sandwiching a wavelength conversion layer such as a quantum dot layer between gas barrier films, the inventors of the present invention examined a constitution in which an end face sealing layer having gas barrier properties is provided on the end faces of a functional layer laminate so as to seal the end faces, as a constitution which can prevent oxygen or moisture from permeating the wavelength conversion layer from the end face and can enlarge the region, in which the wavelength conversion layer can be effectively used, by narrowing the frame portion.

It is considered that in a case where the end face sealing layer is formed on the end faces of the functional layer laminate, from the viewpoint of securing the flatness of the laminated film, securing the area in which the wavelength conversion function can be effectively used, and the like, it is preferable that the end face sealing layer is formed only on the end faces and is not formed on the main surface. That is, in a case where the end face sealing layer is also formed on the main surfaces, the end face sealing layer will be heaped up on the main surfaces, and hence the overall flatness of the laminated film will be impaired. Furthermore, it is considered that the portion wrapped with the end face sealing layer will function as a light blocking layer, and as a result, a non-light-emitting region may occur on the edge of the laminated film, the frame portion may be enlarged, and the effectively usable area may be reduced.

However, through the examination conducted by the inventors of the present invention, it was understood that in a case where the end face sealing layer is formed only on the end faces of the functional layer laminate, due to the partial peeling of the end face sealing layer, moisture or oxygen may permeate from the interface between the end face of the functional layer laminate and the end face sealing layer and reach the wavelength conversion layer, and hence the wavelength conversion layer may deteriorate.

Therefore, in the laminated film of the present invention, the end face sealing layer 16 is formed to cover a region from a portion of one main surface of the functional layer laminate 11 to a portion of the other main surface including the entirety of the end face of the functional layer laminate 11, and the width s, measured from the end face, of the build-up portion M of the end face sealing layer 16 is equal to or greater than 0.01 mm and equal to or smaller than 8% of the length of the main surface.

In a case where the width s of the build-up portion of the end face sealing layer 16 is equal to or smaller than 8% of the length of the main surface, it is possible to secure an area in which the wavelength conversion function of the laminated film 10 can be effectively used and to secure the flatness of the laminated film 10.

Furthermore, in a case where the width s of the build-up portion of the end face sealing layer 16 is equal to or greater than 0.01 mm, it is possible to improve the adhesiveness between the functional layer laminate 11 and the end face sealing layer 16, inhibit moisture or oxygen from permeating from the interface between the end face of the functional layer laminate 11 and the end face sealing layer 16, and prevent the deterioration of the wavelength conversion layer.

In a case where the functional layer laminate 11 has a layer obtained by forming an asperity structure on the surface of a diffusion layer or the like, the asperity structure of the diffusion layer may be concealed by the build-up portion M of the end face sealing layer 16, and hence the diffusion layer may not be able to perform its own function. That is, in a case where the width s of the build-up portion M of the end face sealing layer 16 is large, the effectively usable area is reduced.

In contrast, in the laminated film 10 of the present invention, the width s of the build-up portion of the end face sealing layer 16 is equal to or smaller than 8% of the length of the main surface. Therefore, even in a case where the functional layer laminate 11 has a diffusion layer, it is possible to secure an area in which the function of the diffusion layer can be effectively used.

The width s of the build-up portion M of the end face sealing layer 16 is preferably equal to or smaller than 5% of the length of the main surface and more preferably equal to or smaller than 3% of the length of the main surface, because then an area in which the wavelength conversion function of the laminated film 10 can be effectively used can be secured, the flatness of the laminated film 10 can be secured, and an area in which the diffusion layer can be effectively used can be secured in a case where the functional layer laminate has a diffusion layer.

In a case where the main surface of the functional layer laminate 11 has a rectangular shape, the length of a short side thereof is regarded as the length of the main surface. In a case where the main surface has a circular shape, the diameter thereof is regarded as the length of the main surface. In a case where the main surface has an elliptical shape, the minor axis thereof is regarded as the length of the main surface. In a case where the main surface has a polygonal shape, the diameter of an inscribed circle is regarded as the length of the main surface.

The width s of the build-up portion M of the end face sealing layer 16 can be measured, for example, by performing cross-section cutting on the laminated film by using RETRATOME REM-710 manufactured by YAMATO KOHKI INDUSTRIAL CO., LTD. or the like and observing the cross-section with an optical microscope.

A height t of the end face sealing layer 16 measured from the main surface in a direction perpendicular to the main surface of the functional layer laminate 11 is preferably greater than 0% and equal to or smaller than 20% of the thickness of the functional layer laminate 11, more preferably 1% to 10% of the thickness of the functional layer laminate 11, and even more preferably 1% to 5% of the thickness of the functional layer laminate 11.

It is preferable that the height t of the end face sealing layer 16 measured from the main surface is equal to or smaller than 20% of the thickness of the functional layer laminate 11, because then the flatness of the laminated film 10 can be secured.

Furthermore, it is preferable that the height t is greater than 0% of the thickness of the functional layer laminate 11, because then the adhesiveness between the functional layer laminate 11 and the end face sealing layer 16 is improved, and hence moisture or oxygen can be inhibited from permeating from the interface between the end face of the functional layer laminate 11 and the end face sealing layer 16.

The thickness of the end face sealing layer 16 in a direction perpendicular to the end face of the functional layer laminate 11 is preferably 5 μm to 200 μm, and more preferably 10 μm to 50 μm.

It is preferable that the thickness of the end face sealing layer 16 is equal to or greater than 5 μm, because then the end faces of the functional layer laminate 11 can be adequately covered, and sufficient gas barrier properties can be exhibited.

Furthermore, it is preferable that the thickness of the end face sealing layer 16 is equal to or smaller than 200 μm, because then the enlargement of the frame portion can be inhibited, and the end face sealing layer 16 can exhibit sufficient adhesiveness with respect to the functional layer laminate 11.

For example, in a case where the laminated film 10 as the laminated film of the present invention has a quadrangular planar shape, only two end faces facing each other may be provided with the end face sealing layer covering the entirety of the two end faces, or three end faces except for one end face may be provided with the end face sealing layer covering the entirety of the three end faces. Furthermore, the end face sealing layer may be provided such that it partially covers each of the end faces of the functional layer laminate 11. Where to provide the end face sealing layer may be appropriately set according to the constitution of a backlight unit in which the laminated film is used, the constitution of a laminated film-mounting portion, and the like.

Nonetheless, the end face sealing layer 16 preferably covers the end faces of the functional layer laminate 11 in as large area as possible, and particularly preferably covers the entirety of the end faces of the functional layer laminate 1, because then it is possible to more suitably prevent the deterioration of the wavelength conversion layer 12 such as the deterioration of quantum dots caused by the oxygen or the like permeating from the end face of the functional layer laminate 11.

In a preferred aspect illustrated in the drawing, the end face sealing layer 16 is constituted with three layers including the first layer 30 on the functional layer laminate 11 side, the second layer 32 laminated on the first layer, and the third layer 34 laminated on the second layer 32. However, the present invention is not limited thereto, and the end face sealing layer 16 may be constituted with one layer, two layers, or four or more layers.

In a case where the end face sealing layer 16 has a multilayer structure including two or more layers, by separately imparting the desired function to each of the layers, the gas barrier properties can be further improved than in a case where the end face sealing layer 16 is constituted with a single layer (one layer). For example, in a case where a water-soluble material which exhibits low oxygen permeability at a low humidity and high oxygen permeability at a high humidity is used for the first layer 30, by providing a water vapor barrier layer as the second layer 32, it is possible to make the first layer exhibit low oxygen permeability regardless of humidity. Alternatively, for example, in a case where the adhesiveness between a layer having low oxygen permeability (oxygen barrier layer) and the functional layer laminate 11 (wavelength conversion layer 12) is poor, it is possible to adopt a constitution in which an adhesive layer is provided between the oxygen barrier layer and the functional layer laminate 11.

The material forming each layer constituting the end face sealing layer 16 is not limited, and may be appropriately selected from a resin material, a metal material, and the like according to the function required for each layer.

For example, the end face sealing layer 16 shown in FIG. 3 has a constitution in which an adhesion layer is provided as the first layer 30, an oxygen barrier layer is provided as the second layer 32, and a water vapor barrier layer is provided as the third layer 34.

In a case where an adhesion layer is provided as the first layer 30 on the functional layer laminate 11 side, the adhesiveness between the functional layer laminate 11 and the end face sealing layer 16 can be improved. In a case where an oxygen barrier layer is provided as the second layer 32, the end face sealing layer 16 can exhibit high oxygen barrier properties. In a case where a water vapor barrier layer is provided as the third layer 34, the end face sealing layer 16 can exhibit high water vapor barrier properties, and it is possible to inhibit the oxygen barrier properties of the oxygen barrier layer from deteriorating due to moisture.

The oxygen permeability of the aforementioned oxygen barrier layer is preferably equal to or lower than 1.0 [cc/(m²·day·atm)], more preferably equal to or lower than 1×10⁻¹ [cc/(m²·day·atm)], even more preferably equal to or lower than 1×10⁻² [cc/(m²·day·atm)], and particularly preferably equal to or lower than 1×10⁻³ [cc/(m²·day·atm)].

It is preferable that the material forming the oxygen barrier layer contains polyvinyl alcohol (PVA), an ethylene-vinyl alcohol copolymer (EVOH), and the like.

As the material forming the oxygen barrier layer, commercial products can also be suitably used.

Examples of the commercial products suitably include MAXIVE manufactured by MITSUBISHI GAS CHEMICAL COMPANY, INC., EVAL manufactured by KURARAY CO., LTD., ECOSTAGE manufactured by SAKATA INX CORPORATION, and the like.

Furthermore, the thickness of the oxygen barrier layer is not limited, and may be set such that desired oxygen barrier properties are obtained.

The particles of an inorganic substance (particles formed of an inorganic compound) may be dispersed in the oxygen barrier layer.

In a case where the oxygen barrier layer contains the particles of an inorganic substance, the oxygen permeability can be further reduced, and it is possible to more suitably prevent the wavelength conversion layer 12 from deteriorating due to oxygen or the like permeating from the end face.

The size of the particles of an inorganic substance dispersed in the oxygen barrier layer is not limited, and may be appropriately set according to the thickness of the oxygen barrier layer or the like. The size (maximum length) of the particles of an inorganic substance dispersed in the oxygen barrier layer is preferably less than the thickness of the oxygen barrier layer. Particularly, the smaller the size of the particles, the more advantageous.

The size of the particles of an inorganic substance dispersed in the oxygen barrier layer may be uniform or non-uniform.

The content of the particles of an inorganic substance in the oxygen barrier layer may be appropriately set according to the size of the particles of an inorganic substance or the like.

According to the examinations performed by the inventors of the present invention, the content of the particles of an inorganic substance in the oxygen barrier layer is preferably equal to or smaller than 50% by mass, and more preferably 10% to 30% by mass.

The greater the content of the particles of an inorganic substance is, the further the oxygen permeability is effectively reduced by the particles of an inorganic substance. In a case where the content of the particles of an inorganic substance is equal to or greater than 10% by mass, the effect obtained by the addition of the particles of an inorganic substance becomes more suitable, and an oxygen barrier layer having a low oxygen permeability can be formed.

It is preferable that the content of the particles of an inorganic substance in the oxygen barrier layer is equal to or smaller than 50% by mass, because then the adhesiveness or the durability of the oxygen barrier layer can become sufficient, and the occurrence of cracking at the time of cutting or punching the laminated film can be inhibited.

Specific examples of the particles of an inorganic substance dispersed in the oxygen barrier layer include silica particles, alumina particles, silver particles, copper particles, titanium particles, zirconia particles, tin particles, and the like.

The water vapor transmission rate of the aforementioned water vapor barrier layer at 40° C. and humidity of 90% is preferably equal to or lower than 100 g/(m²·day)/30 μm, and more preferably equal to or lower than 50 g/(m²·day)/30 μm.

It is preferable that the material forming the water vapor barrier layer contains an epoxy resin, a cycloolefin polymer (COP), an ethylene-vinyl alcohol copolymer (EVOH), and the like.

The thickness of the water vapor barrier layer is not limited, and may be set such that desired water vapor barrier properties are obtained.

The water vapor transmission rate is a value measured by a calcium corrosion method (method described in JP2005-283561A).

The material forming the aforementioned adhesion layer may be appropriately selected from the materials that make it possible to secure the adhesiveness between the functional layer laminate 11 and the oxygen barrier layer.

Specifically, an epoxy resin, a urethane resin, and the like can be used.

In the example described above, the end face sealing layer 16 is constituted with the adhesion layer as the first layer 30, the oxygen barrier layer as the second layer 32, and the water vapor barrier layer as the third layer 34. However, the present invention is not limited to this constitution, and for example, a constitution may be adopted in which an end face resin layer is provided as the first layer and a metal layer is provided as the second layer.

In the end face sealing layer 16 constituted as above, the gas barrier properties are exhibited mainly by the metal layer. In a case where an end face resin layer is between the metal layer and the end face of the functional layer laminate 11, it is possible to prevent the occurrence of a defect such as a pinhole in the metal layer by smoothening the underlayer of the metal layer and to improve the gas barrier properties.

Furthermore, a constitution may be adopted in which an underlayer, which becomes a base of the metal layer, is between the end face resin layer and the metal layer.

In addition, a first metal layer may be formed on the end face resin layer by sputtering, and a second metal layer may be formed by a plating treatment by using the first metal layer as an electrode.

Moreover, a resin layer may be formed on the metal layer.

The end face resin layer is formed of a resin material.

As described above, in a case where the end face sealing layer has the end face resin layer, it is possible to smoothen a surface on which the metal layer, which will be described later, is formed (underlayer for forming the metal layer). As a result, it is possible to prevent the occurrence of a defect such as a pinhole in the metal layer and to make the metal layer reliably exhibit gas barrier properties.

The thickness of the end face resin layer is preferably 1 μm to 100 μm, and more preferably 5 μm to 50 μm.

Through examinations, the inventors of the present invention have found that in a case where the end face resin layer is too thin, a defect such as a pinhole occurs at the time of forming the metal layer because the underlayer is not smooth enough.

Furthermore, the inventors have found that in a case where the end face resin layer is too thick, due to the cure shrinkage of the material becoming the end face resin layer that occurs at the time of forming the end face resin layer, the adhesiveness between the end face resin layer and the functional layer laminate 11 may deteriorate.

In addition, because the end face resin layer comes into contact with the support 20 or the organic layer 24 of the gas barrier film 14 and with the wavelength conversion layer 12, the support 20 or the organic layer 24 and the wavelength conversion layer 12 are in communication with each other by bypassing the inorganic layer 26 through the end face resin layer. Accordingly, in a case where the end face resin layer is too thick, the oxygen or moisture passing through the support 20 or the organic layer 24 of the gas barrier film 14 may permeate the end face resin layer and easily permeate the end face of the wavelength conversion layer 12 from the end face resin layer.

Therefore, in a case where the thickness of the end face resin layer is 1 μm to 100 μm, sufficient adhesiveness between the end face resin layer and the functional layer laminate 11 can be secured, and a defect such as a pinhole can be prevented from occurring in the metal layer. Furthermore, the permeation of oxygen or moisture using the end face resin layer as a bypassing route can be inhibited, and hence the deterioration of the wavelength conversion layer 12 can be more suitably prevented.

As described above, the end face resin layer can be a permeation route of oxygen or moisture. Therefore, it is preferable that the end face resin layer has low oxygen permeability.

Specifically, the oxygen permeability of the end face resin layer is preferably equal to or lower than 10 cc/(m²·day·atm), more preferably equal to or lower than 5 cc/(m²·day·atm), and even more preferably equal to or lower than 1 cc/(m²·day·atm).

The lower limit of the oxygen permeability of the end face resin layer is not particularly limited. Basically, the lower the lower limit, the more preferable.

The resin material forming such an end face resin layer is not limited, but is preferably a known resin material which can form the end face resin layer having an oxygen permeability of equal to or lower than 10 cc/(m²·day·atm).

Generally, the end face resin layer is preferably formed by preparing a composition, which contains a compound (a monomer, a dimer, a trimer, an oligomer, a polymer, and the like) that mainly becomes the end face resin layer, that is, a resin layer, an additive such as a cross-linking agent or a surfactant added if necessary, an organic solvent, and the like, coating a surface for forming the end face resin layer with the composition, drying the composition, and, if necessary, polymerizing (cross-linking-curing) a compound mainly constituting the end face resin layer by ultraviolet irradiation, heating, and the like.

It is preferable that the composition for forming the end face resin layer in the laminated film 10 of the present invention contains a polymerizable compound or additionally contains a hydrogen bonding compound. The polymerizable compound is a compound having polymerization properties, and the hydrogen bonding compound is a compound having hydrogen bonding properties.

Basically, it is preferable that the end face resin layer is mainly formed of a polymerizable compound or a hydrogen bonding compound which may be additionally used.

A log P value of a degree of hydrophilicity of the polymerizable compound and the hydrogen bonding compound contained in the composition for forming the end face resin layer is preferably equal to or smaller than 4, and more preferably equal to or smaller than 3.

In the present invention, the Log P value of a degree of hydrophilicity is a logarithm of a partition coefficient of 1-octanol/water. The Log P value can be calculated by a fragment method, an atomic approach method, and the like. The Log P value described in the present specification is a Log P value calculated from the structure of a compound by using ChemBioDraw Ultra 12.0 manufactured by CambridgeSoft Corporation.

As described above, generally, the wavelength conversion layer 12 is obtained by dispersing a material performing an optical function in a resin that becomes a matrix.

In many cases, a hydrophobic resin is used as a matrix for the wavelength conversion layer 12. Particularly, in a case where the wavelength conversion layer 12 is a quantum dot layer, a hydrophobic resin is frequently used as a matrix.

Basically, the adhesion between the wavelength conversion layer 12, which is obtained by dispersing quantum dots and the like in a resin that becomes a matrix, and the end face resin layer is strong. In order to further strengthen the adhesion between the end face resin layer and the wavelength conversion layer 12 in which a hydrophobic matrix is used, it is preferable that the end face resin layer is formed of a hydrophobic compound.

As it is also known, the smaller the log P value of a degree of hydrophilicity of a compound, the higher the hydrophilicity of the compound. That is, in order to form an end face resin layer having strong adhesion with respect to the wavelength conversion layer 12, it is preferable that the polymerizable compound or the hydrogen bonding compound as a main component of the end face resin layer has a large log P value of a degree of hydrophilicity.

In contrast, a resin formed of a compound having high hydrophobicity has a high oxygen permeability. Therefore, in view of the oxygen permeability of the resin layer, it is preferable that the polymerizable compound or the hydrogen bonding compound as a main component of the resin layer has a small log P value of a degree of hydrophilicity.

Accordingly, in a case where the end face resin layer is formed using a polymerizable compound and a hydrogen bonding compound having a log P value of a degree of hydrophilicity of equal to or smaller than 4, it is possible to form an end face resin layer having a sufficiently low oxygen permeability with securing strong adhesion with respect to the wavelength conversion layer 12 by appropriate hydrophobicity.

In view of the oxygen permeability, it is preferable that the polymerizable compound and the hydrogen bonding compound have a small log P value of a degree of hydrophilicity. However, in a case where the log P value of a degree of hydrophilicity is too small, the hydrophilicity may be too high, the adhesion between the end face resin layer and the wavelength conversion layer 12 may be weakened, and the durability of end face resin layer may deteriorate.

Considering the above points, the log P value of a degree of hydrophilicity of the polymerizable compound and the hydrogen bonding compound is preferably equal to or greater than 0.0, and more preferably equal to or greater than 0.5.

The composition forming the end face resin layer in the laminated film 10 of the present invention contains the hydrogen bonding compound, preferably in an amount of equal to or greater than 30 parts by mass and more preferably in an amount of equal to or greater than 40 parts by mass provided that the total amount of solid contents in the composition is 100 parts by mass.

The total amount of solid contents in the composition is the total amount of components that should remain in the end face resin layer to be formed, except for an organic solvent in the composition.

In a case where the solid contents in the composition forming the end face resin layer contain a hydrogen bonding compound in an amount of equal to or greater than 30 parts by mass, the oxygen permeability can be reduced by strengthening the intermolecular interaction.

A hydrogen bond refers to a non-covalent bond that is formed between a hydrogen atom, which forms a covalent bond with an atom having electronegativity higher than that of the hydrogen atom in a molecule, and another atom or atomic group in the same molecule or different molecules by attractive interaction.

The functional group having hydrogen bonding properties is a functional group containing a hydrogen atom which can form such a hydrogen bond. Specific examples of the functional group include a urethane group, a urea group, a hydroxyl group, a carboxyl group, an amide group, a cyano group, and the like.

Specific examples of compounds having these functional groups include monomers and oligomers which are obtained by reacting diisocyanate such as tolylene diisocyanate (TDI), diphenylmethane diisocyanate (MDI), hexamethylene diisocyanate (HDI), isophorone diisocyanate (IPDI), and hydrogenated MDI (HMDI) with polyol such as poly(propyleneoxide)diol, poly(tetramethyleneoxide)diol, ethoxylated bisphenol A, ethoxylated bisphenol S spiroglycol, caprolactone-modified diol, and carbonate diol and hydroxyacrylate such as 2-hydroxyethyl (meth)acrylate, 2-hydroxypropyl (meth)acrylate, glycidyl di(meth)acrylate, and pentaerythritol triacrylate.

Examples of the aforementioned compounds also include an epoxy compound obtained by reacting a compound having an epoxy group with a compound such as a bisphenol A-type compound, a bisphenol S-type compound, a bisphenol F-type compound, an epoxidized oil-type compound, and a phenol novolac-type compound and an epoxy compound obtained by reacting alicyclic epoxy with an amine compound, an acid anhydride, and the like.

Examples of the aforementioned compounds also include a cationically polymerized substance of the aforementioned epoxy compound, polyvinyl alcohol (PVA), an ethylene-vinyl alcohol copolymer (EVOH), a butanediol-vinyl alcohol copolymer, polyacrylonitrile, and the like.

Among these, a compound having an epoxy group and a compound obtained by reacting a compound having an epoxy group are preferable, because these compounds less experience cure shrinkage and have excellent adhesiveness with respect to the laminated film.

Provided that the total amount of solid contents in the composition is 100 parts by mass, the composition forming the end face resin layer in the laminated film 10 of the present invention preferably contains a polymerizable compound having at least one polymerizable functional group selected from a (meth)acryloyl group, a vinyl group, a glycidyl group, an oxetane group, and an alicyclic epoxy group in an amount of equal to or greater than 5 parts by mass, and more preferably contains the polymerizable compound having these polymerizable functional groups in an amount of equal to or greater than 10 parts by mass.

In the laminated film 10 of the present invention, in a case where the solid contents in the composition forming the end face resin layer contain the polymerizable compound having at least one polymerizable functional group selected from a (meth)acryloyl group and the like in an amount of equal to or greater than 5 parts by mass, an end face resin layer exhibiting excellent durability at a high temperature and a high humidity can be realized.

Specific examples of the polymerizable compound having a (meth)acryloyl group include neopentyl glycol di(meth)acrylate, 1,9-nonanediol di(meth)acrylate, tripropylene glycol di(meth)acrylate, ethylene glycol di(meth)acrylate, dicyclopentenyl (meth)acrylate, dicyclopentenyloxyethyl (meth)acrylate, dicyclopentanyl di(meth)acrylate, and the like.

Specific examples of the polymerizable compound having a glycidyl group, an oxetane group, an alicyclic epoxy group, or the like include bisphenol A diglycidyl ether, bisphenol F diglycidyl ether, hydrogenated bisphenol A diglycidyl ether, hydrogenated bisphenol F diglycidyl ether, 1,4-butanediol diglycidyl ether, 1,6-hexanediol diglycidyl ether, glycerin triglycidyl ether, trimethylolpropane triglycidyl ether, and the like.

In the present invention, as the polymerizable compound having a (meth)acryloyl group or a glycidyl group, commercial products can be suitably used.

As the commercial products including the polymerizable compound, MAXIVE manufactured by MITSUBISHI GAS CHEMICAL COMPANY, INC., NANOPOX 450, NANOPOX 500, and NANOPOX 630 manufactured by Evonik Industries, a series compounds such as COMPOCERAN 102 manufactured by Arakawa Chemical Industries, Ltd., FLEP and THIOKOL LP manufactured by Toray Fine Chemicals Co., Ltd., a series of compounds such as LOCTITE E-30CL manufactured by Henkel Japan Ltd., a series of compounds such as EPO-TEX353ND manufactured by Epoxy Technology Inc, and the like can be suitably exemplified.

If necessary, the composition forming the end face resin layer in the laminated film of the present invention may contain a polymerizable compound which does not contain a (meth)acryloyl group, a vinyl group, a glycidyl group, an oxetane group, and an alicyclic epoxy group.

Here, provided that the total amount of solid contents in the composition forming the end face resin layer is 100 parts by mass, the amount of the polymerizable compound, which does not contain the aforementioned functional groups, contained in the composition is preferably equal to or smaller than 3 parts by mass.

The metal layer is a layer which mainly exhibits gas barrier properties in the end face sealing layer 16, and preferably formed by covering the entirety of the end face resin layer (the entirety of the end face resin layer except for a surface of the end face resin layer coming into contact with the end faces of the functional layer laminate 11).

The material forming the metal layer is not limited as long as the material is a metal. The metal layer is preferably a metal layer formed by any method among a sputtering method, a vacuum vapor deposition method, an ion plating method, a plasma CVD method, and a metal plating treatment.

Specifically, the material forming the metal layer is preferably either at least one kind of metal selected from the group consisting of aluminum, titanium, chromium, nickel, tin, copper, silver, and gold or an alloy containing at least one kind of metal among the above metals.

Particularly, it is preferable that the metal layer is formed by a metal plating treatment, because then a thick metal layer can be formed, high gas barrier properties can be secured, the productivity becomes high, and the metal layer having a uniform thickness can be easily formed on the entirety of the end face resin layer even though the surface of the end face resin layer is a curved surface.

As the method of the metal plating treatment for forming the metal layer, it is possible to use known methods such as an electroplating treatment and an electroless plating treatment. Among these, it is more preferable to use an electroless plating treatment for forming the metal layer, because then a metal layer having a uniform thickness can be formed simply by immersing the functional layer laminate into a plating liquid, and the metal layer can be easily formed.

Examples of metal materials suitable for the electroless plating treatment include nickel, copper, tin, gold, and the like.

From the viewpoint of securing gas barrier properties, productivity, and the like, the thickness of the metal layer is preferably 1 μm to 100 μm, and more preferably 5 μm to 50 μm.

From the viewpoint of securing gas barrier properties, it is preferable that the number of pinholes in the metal layer is small. In the present invention, a pinhole means an uncoated portion (a portion where the metal layer is missed) having a size equal to or greater than 1 μm that is seen in a case where the metal layer is observed with an optical microscope. The pinhole has any shape such as a polygonal shape or a linear shape. The number of pinholes is preferably equal to or smaller than 50 pinholes/mm², more preferably equal to or smaller than 20 pinholes/mm², and particularly preferably equal to or smaller than 5 pinholes/mm². The smaller the number of pinholes, the more preferable. The lower limit of the number of pinholes is not particularly limited.

The underlayer is a layer which is laminated on the end face resin layer and becomes the base of the metal layer. The underlayer is provided if necessary according to the method for forming the metal layer, at the time of forming the metal layer.

For example, in a case where the metal layer is formed by an electroplating treatment, as a member functioning as an electrode (cathode) at the time of the electroplating treatment, the underlayer having high conductivity is provided.

Furthermore, in a case where the metal layer is formed by an electroless plating treatment, in order to improve the adhesiveness between the end face of the functional layer laminate 11 and the plating formed by the electroless plating treatment, the underlayer having high conductivity is also provided.

Such an underlayer having high conductivity is not limited, and examples thereof include a resin layer containing conductive particles that is formed by a method of coating the end face resin layer with a conductive paint obtained by dispersing fine particles having high conductivity such as metal nanoparticles and a layer having high conductivity such as a metal layer that is formed by a sputtering method, a vacuum vapor deposition method, an ion plating method, a plasma CVD method, and the like.

Examples of the conductive paint used as a material of the underlayer include a plating primer containing colloidal palladium (nucleophilic catalyst) or the like as a main component.

As the material forming the layer which can be formed by any of the methods among a sputtering method, a vacuum vapor deposition method, an ion plating method, and a plasma CVD method, either at least one kind of metal selected from the group consisting of aluminum, titanium, chromium, copper, and nickel or an alloy containing at least one kind of metal of these is preferable, and either at least one kind of metal selected from the group consisting of aluminum, titanium, and chromium or an alloy containing at least one kind of metal among these is particularly preferable. Presumably, in a case where a metal (aluminum, titanium, or chromium) having high ionization tendency is used, an oxide of a metal or a nitride of a metal may be easily formed in the interface between the metal and a resin, and hence the adhesiveness may be improved.

It is preferable that the underlayer is formed by a method of coating the end face resin layer with the conductive paint because then the underlayer is easily formed.

The thickness of the underlayer is not limited as long as the metal layer can be properly formed. From the viewpoint of the adhesiveness between the end face resin layer and the metal layer, the coating properties, and the like, the thickness of the underlayer is preferably 0.1 μm to 1.0 μm.

It goes without saying that the end face sealing layer 16 may have layers other than the aforementioned layers.

In a case where the end face sealing layer 16 is constituted with a plurality of layers, at least the layer on the outermost surface side may be formed on the main surface of the functional layer laminate 11.

For example, in a case where the end face sealing layer 16 is constituted with three layers, only the third layer may be formed on the main surface of the functional layer laminate 11. Alternatively, the second layer may be formed on the main surface of the functional layer laminate 11, and the third layer may be formed to cover the second layer on the main surface. As another option, the first layer may be formed on the main surface of the functional layer laminate 11, the second layer may be formed to cover the first layer on the main surface, and the third layer may be formed to cover the second layer. That is, the build-up portion M may be formed only of the third layer, the second and third layers, or the first, second, and third layers.

Next, an example of a method for manufacturing the laminated film of the present invention will be described. Hereinafter, the method will be described mainly based on the laminated film 10 shown in FIG. 1 for example, but in other aspects, a laminated film can also be manufactured based on the method.

First, the functional layer laminate 11 is prepared.

As the preparation method of the functional layer laminate 11, as described above, the organic layer 24 is formed on the surface of the support 20 by a coating method or the like, and the inorganic layer 26 is formed on the surface of the organic layer 24 by plasma CVD or the like. Then, the organic layer 28 is formed on the surface of the inorganic layer 26 by a coating method or the like, thereby preparing the gas barrier film 14.

It is preferable that the formation of the organic layer and the inorganic layer is performed by a so-called roll-to-roll method. In the following description, “roll-to-roll” will be referred to as “RtoR” as well.

Meanwhile, a composition is prepared which contains an organic solvent, a compound forming a resin that becomes a matrix, quantum dots and the like and becomes the wavelength conversion layer 12 such as a quantum dot layer.

Two sheets of gas barrier films 14 are prepared, and the surface of the organic layer 28 of one sheet of the gas barrier films 14 is coated with the composition that becomes the wavelength conversion layer 12. Furthermore, the other sheet of the gas barrier films 14 is laminated on the composition in a state where the organic layer 28 faces the composition side, and ultraviolet curing or the like is performed, thereby preparing a laminate in which the gas barrier film 14 is laminated on both surfaces of the wavelength conversion layer 12.

The prepared laminate is cut in a predetermined size, thereby preparing the functional layer laminate 11.

The method for cutting the laminate is not limited, and it is possible to use various known methods such as a method of physically cutting the laminate by using a blade such as a Thomson blade and a method of cutting the laminate by laser irradiation.

Furthermore, after the laminate is processed in a predetermined shape, for example, the end faces thereof may be subjected to polishing.

Then, on the end faces of the prepared functional layer laminate 11, the aforementioned end face sealing layer 16 is formed.

The method for forming the end face sealing layer 16 may be appropriately selected according to the material forming the end face sealing layer 16.

In a case where a resin layer such as the oxygen barrier layer, the water vapor barrier layer, the end face resin layer, or the like described above is formed, a composition containing a compound that becomes the resin layer is prepared, the end face of the functional layer laminate 11 is coated with the composition, the composition is dried, and, if necessary, the compound mainly constituting the resin layer is polymerized by ultraviolet irradiation, heating, or the like, thereby forming the resin layer.

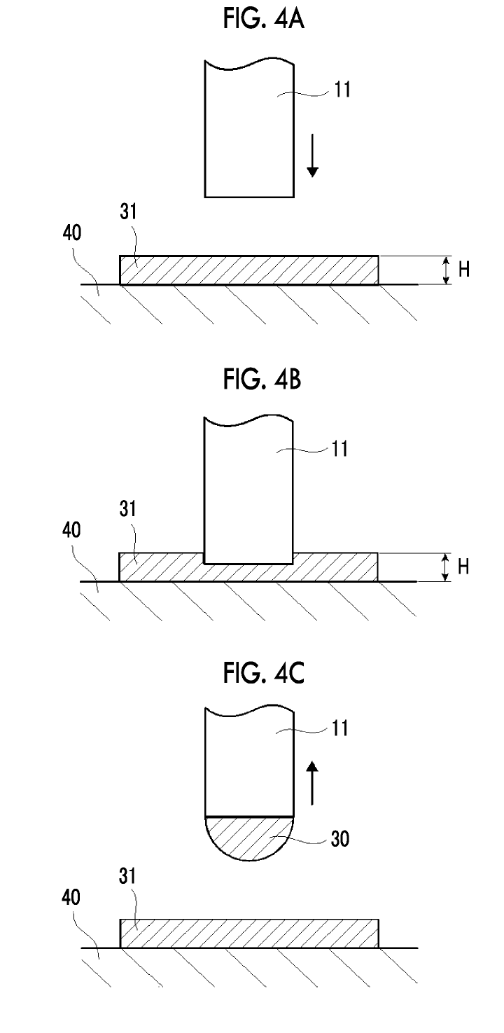

As the method for coating the end faces of the functional layer laminate 11 with the composition, it is possible to use known methods such as ink jet, spray coating, and dipping (immersion coating). FIGS. 4A to 4C show, as a preferred coating method, a method in which the coating is performed by the transfer of a liquid film.

In this coating method, first, as shown in FIG. 4A, a liquid film 31 of the composition that becomes the resin layer is formed on a flat plate 40 (for example, a glass plate or a tray). A thickness H of the liquid film 31 may be appropriately set according to the thickness of the intended resin layer, the concentration of solid contents in the composition, and the like.

The size of the liquid film 31 in the surface direction is not particularly limited as long as the entirety of one end face of the functional layer laminate 11 can come into contact with the liquid film 31. For example, the length of one side of the liquid film 31 may be larger than the length of the edge side of the functional layer laminate 11.

Then, as shown in FIG. 4B, the end face of the functional layer laminate 11 is brought into contact with the liquid film 31. Thereafter, as shown in FIG. 4C, the functional layer laminate 11 is lifted up in a vertical direction such that a predetermined amount of the composition that becomes the resin layer adheres to the end face of the functional layer laminate 11.

At this time, the cross-sectional shape of the composition, which has adhered to the end face of the functional layer laminate 11, perpendicular to the extension direction of the end face becomes approximately circular due to the surface tension of the composition.

The amount of the end face to be immersed in the liquid film 31 and the thickness H of the liquid film 31 may be appropriately set according to the thickness of the resin layer to be formed, the amount of the composition built up on the main surface of the functional layer laminate 11 (the width s and the height t of the build-up portion M), and the like.

After the composition is caused to adhere to all the end faces of the functional layer laminate 11 as described above, the composition having adhered to the end faces of the functional layer laminate 11 is dried and, if necessary, cured by ultraviolet irradiation, heating, and the like, thereby forming the intended resin layer.

In the example shown in FIG. 4C, a constitution is illustrated in which the end face of the functional layer laminate 11 is brought into contact with the liquid film 31, and then the functional layer laminate 11 is moved up in the vertical direction such that the liquid film 31 and the functional layer laminate 11 are separated from each other. However, the present invention is not limited thereto, and the liquid film 31 (flat plate 40) may be moved down in the vertical direction, or the functional layer laminate 11 and the liquid film 31 (flat plate 40) may be moved respectively.

In the example shown in FIG. 4B, a constitution is illustrated in which the end face of the functional layer laminate 11 is moved down in the vertical direction such that the end face is brought into contact with the liquid film 31. However, the present invention is not limited thereto as long as the end face can be brought into contact with the liquid film 31.

In the examples shown in FIGS. 4A to 4C, a constitution is illustrated in which the end face of one sheet of functional layer laminate 11 is brought into contact with the liquid film 31. However, the present invention is not limited thereto, and a constitution may be adopted in which a plurality of sheets of functional layer laminates 11 are collectively brought into contact with the liquid film 31.

For example, functional layer laminates 11 and spacers may be alternately laminated such that the functional layer laminates 11 are separated from each other, and in this state, the end faces thereof may be brought into contact with the liquid film 31 of the composition forming the end face sealing layer 16 in the same manner as described above, such that the end face sealing layer 16 is formed on the end faces of each of the functional layer laminates 11.

In the examples shown in FIGS. 4A to 4C, a constitution is illustrated in which the liquid film 31 of the composition is formed on the flat plate 40, and the end face of the functional layer laminate 11 is brought into contact with the liquid film 31, such that the end face of the functional layer laminate 11 is coated with the composition that becomes the resin layer. However, the present invention is not limited thereto.

For example, a constitution may be adopted in which the edge of the functional layer laminate is immersed in a container containing the composition that becomes the resin layer, such that each end face is coated with the composition that becomes the resin layer.

For example, in a case where the end face sealing layer 16 having the adhesion layer, the oxygen barrier layer, and the water vapor barrier layer described above is formed, the adhesion layer may be formed on the end faces of the functional layer laminate 11 by the aforementioned coating method, the oxygen barrier layer may be formed on the end faces (adhesion layer) of the functional layer laminate, on which the adhesion layer is formed, by the aforementioned coating method, and the water vapor barrier layer may be formed on the end faces (oxygen barrier layer) of the functional layer laminate 11, on which the oxygen barrier layer is formed, by the aforementioned coating method.

Furthermore, for example, in a case where the end face sealing layer 16 having the end face resin layer, the underlayer, and the metal layer described above is formed, the end face resin layer is formed on the end faces of the functional layer laminate 11 by the aforementioned coating method, the underlayer is formed on the end face resin layer, and then the metal layer is formed on the underlayer.

As described above, as the method for forming the underlayer, it is possible to use a sputtering method, a vacuum vapor deposition method, an ion plating method, a plasma CVD method, or a coating method. As the method for coating the end face resin layer with the conductive paint as the underlayer, for example, the coating method performed by the transfer of a liquid film can be suitably used as in a case where the aforementioned end face resin layer is formed. That is, for the functional layer laminate 11 on which the end face resin layer is formed, by the same method as that illustrated in FIGS. 4A to 4C, the conductive paint that becomes the underlayer is caused to adhere onto the end face resin layer. Then, by drying and curing the paint, the underlayer can be formed.

As described above, as the method for forming the metal layer, it is possible to use an electroless plating treatment, an electroplating treatment, a sputtering method, a vacuum vapor deposition method, an ion plating method, a plasma CVD method, and the like.

As the method of the electroless plating treatment, the methods known in the related art can be used. For example, by immersing the end faces of the functional layer laminate 11, on which the end face resin layer and the underlayer are formed, in an electroless plating liquid such that a metal film is precipitated on the underlayer, the metal layer can be formed.

In this way, the laminated film 10 of the present invention is prepared.

The method for manufacturing the laminated film of the present invention is not limited to the above examples. However, it is preferable that the resin layer is formed by coating, that is, it is preferable that each layer constituting the end face sealing layer 16 is formed in a liquid phase, because then the laminated film can be easily manufactured, a large-scale apparatus is not required, and the productivity or the cost become excellent.

Hitherto, the laminated film of the present invention has been specifically described, but the present invention is not limited to the above embodiments. It goes without saying that the present invention may be ameliorated or modified in various ways within a scope that does not depart from the gist of the present invention.

### EXAMPLES

Hereinafter, the present invention will be more specifically described based on specific examples of the present invention. The present invention is not limited to the examples described below, and the materials, the amount and proportion of the materials used, the treatment content, the treatment sequence, and the like shown in the following examples can be appropriately modified as long as the modification does not depart from the gist of the present invention.

### Example 1

As Example 1, the laminated film 10 having an end face sealing layer constituted with one layer was prepared.

<Preparation of Gas Barrier Film 14>

<<Support 20>>

As a support of the gas barrier film 14, a polyethylene terephthalate film (PET film, manufactured by Toyobo Co., Ltd., trade name: COSMOSHINE A4300, thickness: 50 μm, width: 1,000 mm, length: 100 m) was used.

<<Formation of Organic Layer 24>>

The organic layer 24 was formed on one surface of the support 20 as below.

First, a composition for forming the organic layer 24 was prepared. Specifically, trimethylolpropane triacrylate (TMPTA, manufactured by Daicel SciTech) and a photopolymerization initiator (manufactured by Lamberti S.p.A, ESACURE KTO46) were prepared, weighed such that a mass ratio of TMPTA:photopolymerization initiator became 95:5, and dissolved in methyl ethyl ketone, thereby preparing a composition with a concentration of solid contents of 15%.

By using the composition, the organic layer 24 was formed on one surface of the support 20 by a general film forming device which forms a film by a coating method using RtoR.

First, by using a die coater, one surface of the support 20 was coated with the composition. The support 20 having undergone coating was passed through a drying zone with a temperature of 50° C. for 3 minutes and then irradiated with ultraviolet rays (cumulative irradiation amount: about 600 mJ/cm²) such that the composition was cured, thereby forming the organic layer 24.

Furthermore, in the pass roll obtained immediately after the ultraviolet ray curing, as a protective film, a polyethylene film (PE film, manufactured by Sun A Kaken Co., Ltd., trade name: PAC 2-30-T) was bonded to the surface of the organic layer 24, and the resulting film was transported and wound up.

The thickness of the formed organic layer 24 was 1 μm.

<<Formation of Inorganic Layer 26>>

Then, by using a CVD device using RtoR, the inorganic layer 26 (silicon nitride (SiN) layer) was formed on the surface of the organic layer 24.

The support 20 on which the organic layer 24 was formed was fed from a feeding machine, and before an inorganic layer was formed, the protective film was peeled off after the laminate passed the last film surface-touching roll. Then, on the exposed organic layer 24, the inorganic layer 26 was formed by plasma CVD.

For forming the inorganic layer 26, as raw material gases, silane gas (flow rate: 160 sccm), ammonia gas (flow rate: 370 sccm), hydrogen gas (flow rate: 590 sccm), and nitrogen gas (flow rate: 240 sccm) were used. As a power source, a high-frequency power source having a frequency of 13.56 MHz was used. The film forming pressure was 40 Pa.

The thickness of the formed inorganic layer 26 was 50 nm.

The flow rate represented by the unit sccm is a value expressed in terms of a flow rate (cc/min) at 1,013 hPa and 0° C.

<<Formation of Organic Layer 28>>

Furthermore, the organic layer 28 was laminated on the surface of the inorganic layer 26 as below.

First, a composition for forming the organic layer 28 was prepared. Specifically, a urethane bond-containing acryl polymer (manufactured by TAISEI FINE CHEMICAL CO., LTD., ACRIT 8BR500, mass-average molecular weight: 250,000) and a photopolymerization initiator (IRGACURE 184 manufactured by BASF SE) were prepared, weighed such that a mass ratio of urethane bond-containing acryl polymer:photopolymerization initiator became 95:5, and dissolved in methyl ethyl ketone, thereby preparing a composition with a concentration of solid contents of 15% by mass.

By using the composition, the organic layer 28 was formed on the surface of the inorganic layer 26 by using a general film forming device that forms a film by a coating method using RtoR.

First, by using a die coater, the inorganic layer 26 was coated with the composition. The support 20 having undergone coating was passed through a drying zone with a temperature of 100° C. for 3 minutes, thereby forming the organic layer 28.

In this way, the gas barrier film 14 shown in FIG. 2 was prepared in which the organic layer 24, the inorganic layer 26, and the organic layer 28 were formed on the support 20. The thickness of the formed organic layer 24 was 1 μm.

In the pass roll obtained immediately after drying of the composition, as a protective film, a polyethylene film was bonded to the surface of the organic layer 28 in the same manner as described above, and then the gas barrier film 14 was wound up.

<Preparation of Functional Layer Laminate 11>

A composition having the following makeup was prepared which was for forming a quantum dot layer as the wavelength conversion layer 12.

### (Makeup of Composition)

| | | |
|---|---|---|
| Toluene dispersion liquid of quantum dot 1 | 10 | parts by mass |
| (emission maximum: 520 mn) | | |
| Toluene dispersion liquid of quantum dot 2 | 1 | part by mass |
| (emission maximum: 630 mn) | | |
| Lauryl methacrylate | 2.4 | parts by mass |
| Trimethylolpropane triacrylate | 0.54 | parts by mass |
| Photopolymerization initiator (IRGACURE 819, | 0.009 | parts by mass |
| manufactured by BASF SE) | | |

As the quantum dots 1 and 2, the following nanocrystals having a core-shell structure (InP/ZnS) were used.

Quantum dot 1: INP 530-10 (manufactured by NN-LABS, LLC)

Quantum dot 2: INP 620-10 (manufactured by NN-LABS, LLC)

The viscosity of the prepared composition was 50 mPa·s.

By using the composition and a general film forming device that forms a film by a coating method using RtoR, a laminate was prepared in which the gas barrier film 14 was laminated on both surfaces of the wavelength conversion layer 12.

Two sheets of gas barrier films 14 were loaded on the film forming device in a predetermined position and transported. First, the protective film of one of the gas barrier films was peeled, and then the surface of the organic layer 28 was coated with the composition by using a die coater. Thereafter, the protective film was peeled from the other gas barrier film 14, and then the gas barrier film 14 was laminated in a state where the organic layer 28 faced the composition.

Furthermore, the laminate in which the composition that becomes the wavelength conversion layer 12 was sandwiched between the gas barrier films 14 was irradiated with ultraviolet rays (cumulative irradiation amount: about 2,000 mJ/cm²) such that the composition was cured, thereby forming the wavelength conversion layer 12. In this way, a laminate was prepared in which the gas barrier film 14 was laminated on both surfaces of the wavelength conversion layer 12.

The thickness of the wavelength conversion layer 12 was 46 μm, and the thickness T of the laminate was 150 μm.

By using a Thomson blade with a blade edge angle of 17°, the prepared laminate was cut in the form of a 50 mm×100 mm sheet, thereby obtaining the functional layer laminate 11.

<<Formation of End Face Sealing Layer>>

As a composition forming the end face sealing layer 16, a composition having the following solid contents was prepared. The amount of each of the components making up the composition is part by mass calculated in a case where the total amount of the solid contents is regarded as 100 parts by mass.

| | |
|---|---|
| Main agent of two liquid-type thermosetting | 32 parts by mass |
| epoxy resin (manufactured by MITSUBISHI | |
| GAS CHEMICAL COMPANY, INC., M-100) | |
| Curing agent of two liquid-type thermosetting | 68 parts by mass |
| epoxy resin (manufactured by MITSUBISHI | |
| GAS CHEMICAL COMPANY, INC., C-93) | |
| 1-Butanol | 60 parts by mass |

The flat plate 40 was coated with the prepared composition, thereby forming the liquid film 31 having a thickness of 1,000 μm. Then, as shown in FIGS. 4A to 4C, the end faces of the functional layer laminate 11 were brought into contact with the liquid film 31 by pressing the functional layer laminate 11 to a depth of 300 μm. Thereafter, the functional layer laminate 11 was lifted up in the vertical direction, thereby causing a predetermined amount of the composition to adhere to the end faces. Subsequently, the composition was dried and cured for 10 minutes at 80° C., thereby forming the end face sealing layer 16. In this way, the laminated film 10 was prepared.

In the prepared laminated film 10, the end face sealing layer 16 covered a portion of the gas barrier layer 14 and the optically functional layer 12 throughout the entire region of the end faces of the functional layer laminate 11.

A sample of the prepared laminated film 10 was subjected to cross-section cutting by using RETRATOME REM-710 manufactured by YAMATO KOHKI INDUSTRIAL CO., LTD., the cross-section thereof was observed with an optical microscope, and the width s of the build-up portion M of the end face sealing layer 16 and the height t of the build-up portion M from the main surface were measured. As a result, the width s was 3.8 mm, and the height t from the main surface was 33 μm. Furthermore, the thickness of the end face sealing layer was 47 μm.

Accordingly, the width s of the build-up portion M was 7.6% of the length of the main surface, and the height t from the main surface was 22% of the thickness of the functional layer laminate 11.

Furthermore, on a biaxially oriented polyester film (manufactured by TORAY INDUSTRIES, INC., LUMIRROR T60), a sample for measuring oxygen permeability having a thickness of 100 μm was prepared exactly in the same manner as used for preparing the end face sealing layer 16. Then, the sample for measuring oxygen permeability was peeled from the polyester film, and by using a measurement instrument (manufactured by NIPPON API CO., LTD.) adopting an APIMS method (atmospheric pressure ionization mass spectrometry), the oxygen permeability was measured under the condition of a temperature of 25° C. and a humidity of 60% RH.

As a result, the oxygen permeability of the sample for measuring oxygen permeability, that is, the oxygen permeability of the end face sealing layer 16 was 0.9 cc/(m²·day·atm).

### Comparative Example 1

A laminated film was prepared in the same manner as in Example 1, except that the end face sealing layer was not formed.

### Comparative Example 2

A laminated film was prepared in the same manner as in Example 1, except that the coating condition of the end face sealing layer 16 was changed such that the thickness of the liquid film 31 became 50 μm, and the end faces of the functional layer laminate 11 were brought into contact with the liquid film 31 by pressing the functional layer laminate 11 to a depth of 5 μm.

The width s of the build-up portion M of the end face sealing layer 16 of the prepared laminated film 10 and the height t of the build-up portion M from the main surface were measured. As a result, the width s was 0.008 mm, and the height t from the main surface was 1 μm. Furthermore, the thickness of the end face sealing layer was 40 μm.

Accordingly, the width s of the build-up portion M was less than 0.01 mm, and the height t from the main surface was 0.7% of the thickness of the functional layer laminate 11.

In addition, the oxygen permeability of the end face sealing layer 16 was 1.0 cc/(m²·day·atm).

### Comparative Example 3

A laminated film was prepared in the same manner as in Example 1, except that the coating condition of the end face sealing layer 16 was changed such that the thickness of the liquid film 31 became 1,000 μm, and the end faces of the functional layer laminate 11 were brought into contact with the liquid film 31 by pressing the functional layer laminate 11 to a depth of 500 μm.

The width s of the build-up portion M of the end face sealing layer 16 of the prepared laminated film 10 and the height t of the build-up portion M from the main surface were measured. As a result, the width s was 4.3 mm, and the height t from the main surface was 45 μm. Furthermore, the thickness of the end face sealing layer was 48 μm.

Accordingly, the width s of the build-up portion M was 8.6% of the length of the main surface, and the height t from the main surface was 30% of the thickness of the functional layer laminate 11.

In addition, the oxygen permeability of the end face sealing layer 16 was 1.0 cc/(m²·day·atm).

### Example 2

A laminated film was prepared in the same manner as in Example 1, except that the coating condition of the end face sealing layer 16 was changed such that the thickness of the liquid film 31 became 500 μm, and the end faces of the functional layer laminate 11 were brought into contact with the liquid film 31 by pressing the functional layer laminate 11 to a depth of 400 μm.

The width s of the build-up portion M of the end face sealing layer 16 of the prepared laminated film 10 and the height t of the build-up portion M from the main surface were measured. As a result, the width s was 1.0 mm, and the height t from the main surface was 14 μm. Furthermore, the thickness of the end face sealing layer was 29 μm.

Accordingly, the width s of the build-up portion M was 2% of the length of the main surface, and the height t from the main surface was 19% of the thickness of the functional layer laminate 11.

In addition, the oxygen permeability of the end face sealing layer 16 was 1.0 cc/(m²·day·atm).

### Example 3

As Example 3, the laminated film 10 was prepared in the same manner as in Example 1, except that an end face sealing layer constituted with two layers was formed.

<Formation of End Face Sealing Layer 16>

The end face sealing layer 16 constituted with two layers was formed on the end faces of the functional layer laminate 11. Each of the layers was formed by the same coating method performed by transfer as that used for forming the end face sealing layer of Example 1.

The thickness of the first layer was 2 μm, the thickness of the second layer was 30 μm, and hence the total thickness was 32 μm.

<<First Layer>>

| | | |
|---|---|---|
| Main agent of two liquid-type thermosetting | 2 | parts by mass |
| epoxy resin (manufactured by Henkel Japan Ltd., | | |
| E-30CL) | | |
| Curing agent of two liquid-type thermosetting | 1 | part by mass |
| epoxy resin (manufactured by Henkel Japan Ltd., | | |
| E-30CL) | | |
| 1-Butanol | 97 | parts by mass |

<<Second Layer>>

| | |
|---|---|
| Polyvinyl alcohol-based resin (manufactured by | 40 parts by mass |
| Nippon Synthetic Chemical Industry Co., Ltd., | |
| G polymer: OKS-8049) | |
| Pure water | 44 parts by mass |
| 2-Propanol | 16 parts by mass |

The width s of the build-up portion M of the end face sealing layer 16 of the prepared laminated film 10 and the height t of the build-up portion M from the main surface were measured. As a result, the width s was 0.5 mm, and the height t from the main surface was 16 μm.

Accordingly, the width s of the build-up portion M was 1% of the length of the main surface, and the height t from the main surface was 11% of the thickness of the functional layer laminate 11.

In addition, the oxygen permeability of the end face sealing layer 16 was 0.01 cc/(m²·day·atm).

### Example 4

A laminated film was prepared in the same manner as in Example 3, except that the end face sealing layer 16 was formed by laminating a diffusion layer on one surface of the functional layer laminate 11.

The diffusion layer was formed as below.

A coating solution 1 for a light diffusion layer shown below was filtered through a polypropylene filter having a pore size of 30 μm, thereby preparing a coati solution for a light diffusion layer.

Coating solution 1 for light diffusion layer

| | | |
|---|---|---|
| DPHA | 15 | g |
| PET-30 | 73 | g |
| IRGACURE 184 | 1 | g |
| IRGACURE 127 | 1 | g |
| Styrene particles having a particle diameter of 5.0 μm | 8 | g |
| Benzoguanamine particles having a particle diameter of 1.5 μm | 2 | g |
| Methyl ethyl ketone (MEK) | 50 | g |
| Methyl isobutyl ketone (MIBK) | 50 | g |

The used compounds are as below.
DPHA: mixture of dipentaerythritol pentaacrylate and dipentaerythritol hexaacrylate [manufactured by Nippon Kayaku Co., Ltd.]
PET-30: pentaerythritol triacrylate [manufactured by Nippon Kayaku Co., Ltd.]
IRGACURE 127: polymerization initiator [manufactured by Ciba Specialty Chemicals Inc.]
IRGACURE 184: polymerization initiator [manufactured by Ciba Specialty Chemicals Inc.]

(Formation of Diffusion Layer)

By using a general die coater, one surface of the functional layer laminate 11 was coated with the coating solution for a light diffusion layer by directly jetting the coating solution to the surface. The coating was performed under the condition of a transport speed of 30 m/min. The coating solution was dried for 15 seconds at 30° C. and then for 20 seconds at 90° C. Then, with nitrogen purging, by using a 160 W/cm air-cooled metal halide lamp (manufactured by EYE GRAPHICS Co., Ltd.), the coating layer was cured by being irradiated with ultraviolet rays in an irradiation amount of 90 mJ/cm² at an oxygen concentration of 0.2%, thereby forming a diffusion layer. The thickness of the obtained diffusion layer was 8.0 μm.

Thereafter, the end face sealing layer 16 was formed in the same manner as in Example 3.

The width s of the build-up portion M of the end face sealing layer 16 of the prepared laminated film 10 and the height t of the build-up portion M from the main surface were measured. As a result, the width s was 0.5 mm, and the height t from the main surface was 16 μm.

Accordingly, the width s of the build-up portion M was 1% of the length of the main surface, and the height t from the main surface was 11% of the thickness of the functional layer laminate 11.

Furthermore, the oxygen permeability of the end face sealing layer 16 was 0.01 cc/(m²·day·atm).

### Example 5

A laminated film was prepared in the same manner as in Example 1, except that the coating condition of the end face sealing layer 16 was changed such that the thickness of the liquid film 31 became 50 μm, and the end faces of the functional layer laminate 11 were brought into contact with the liquid film 31 by pressing the functional layer laminate 11 to a depth of 30 μm.

The width s of the build-up portion M of the end face sealing layer 16 of the prepared laminated film 10 and the height t of the build-up portion M from the main surface were measured. As a result, the width s was 0.05 mm, and the height t from the main surface was 3 μm. Furthermore, the thickness of the end face sealing layer was 41 μm.

Accordingly, the width s of the build-up portion M was 0.1% of the length of the main surface, and the height t from the main surface was 2.0% of the thickness of the functional layer laminate 11.

In addition, the oxygen permeability of the end face sealing layer 16 was 1.0 cc/(m²·day·atm).

[Evaluation]

The prepared laminated films of Examples 1 and 5 and Comparative Examples 1 to 4 were evaluated in terms of the performance deterioration (barrier properties) of the edge.

<Barrier Properties>

By measuring the degree of performance deterioration of the edge, the barrier properties of the end face sealing layer were evaluated.

First, an initial luminance (Y0) of the laminated film was measured in the following sequence. A commercial tablet terminal (Kindle (registered trademark) “Fire HDX 7” manufactured by Amazon.com, Inc) was disassembled, and the backlight unit was taken out. The laminated film was disposed on the light guide plate of the backlight unit taken out, and two prism sheets of directions orthogonal to each other were stacked on the laminated film. The luminance of light, which was emitted from a blue light source and transmitted through the laminated film and two prism sheets, was measured using a luminance meter (SR3, manufactured by TOPCON CORPORATION) installed in a position 740 mm distant from light guide plate in a direction perpendicular to the surface of the light guide plate, and taken as the luminance of the laminated film.

Then, the laminated film was put into a constant-temperature tank kept at 60° C. and a relative humidity of 90% and stored as it was for 1,000 hours. After 1000 hours, the laminated film was taken out, and a luminance (Y1) after the high-temperature high-humidity testing was measured in the same sequence as described above. By using the following equation, a rate of change (ΔY) of the luminance (Y1) after the high-temperature high-humidity testing with respect to the initial luminance (Y0) was calculated. By using ΔY as a parameter of a luminance change, the barrier properties were evaluated based on the following standards.

ΔY [%]=(Y0−Y1)/Y0×100

A: ΔY≤5%

B: 5%<ΔY<15%

C: 15%≤ΔY

<Effective Area>

Furthermore, based on a ratio of the initial luminance (Y0) measured as above to the initial luminance of Comparative Example 1 (with unsealed end faces), the effective area was evaluated based on the following standards.

A: equal to or higher than 95%

B: equal to or higher than 85% and less than 95%

C: less than 85%

The results are shown in Table 1.

TABLE 1

| | | Build-up portion M of end face sealing layer | | | | | | |
|---|---|---|---|---|---|---|---|---|
| | | Width | | Height | | | | |
| | | | Ratio to | | Ratio to | | | |
| | | | length of | | thickness of | | Evaluation | |
| | Number of | Width s | main surface | Height t | laminate | Diffusion | Barrier | Effective |
| Test No. | layers | (mm) | (%) | (μm) | (%) | layer | properties | area |
| Example 1 | 1 | 3.8 | 7.6 | 33 | 22 | Absent | B | B |
| Comparative | — | — | — | — | — | Absent | C | A |
| Example 1 | | | | | | | | |
| Comparative | 1 | 0.008 | 0.02 | 1 | 0.7 | Absent | C | A |
| Example 2 | | | | | | | | |
| Comparative | 1 | 4.3 | 8.6 | 45 | 30 | Absent | A | C |
| Example 3 | | | | | | | | |
| Example 2 | 1 | 1.0 | 2 | 29 | 19 | Absent | B | A |
| Example 3 | 2 | 0.5 | 1 | 16 | 11 | Absent | A | A |
| Example 4 | 2 | 0.5 | 1 | 19 | 13 | Present | A | A |
| Example 5 | 1 | 0.05 | 0.1 | 3 | 2 | Absent | A | A |

From Table 1, it is understood that in the laminated film of the present invention, the non-light-emitting region of the edge is further reduced than in comparative examples, the end face sealing layer blocks oxygen and water, and hence the deterioration of quantum dots (optically functional layer) can be prevented.

From the comparison between Example 1 and Example 2, it is understood that in a case where the end face sealing layer is constituted with two layers, the barrier properties can be further improved.

From the comparison between Example 2 and Example 3, it is understood that the width s of the build-up portion M is preferably equal to or smaller than 5%.

From the comparison between Examples 1 to 4, it is preferable that the height t from the main surface is equal to or smaller than 10%.

The above results clearly show the effects of the present invention.

### EXPLANATION OF REFERENCES

10: laminated film
11: functional layer laminate
12: wavelength conversion layer
14: gas barrier film
16: end face sealing layer
20: support
24, 28: organic layer
26: inorganic layer
30: first layer
31: liquid film
32: second layer
34: third layer
40: flat plate

What is claimed is:

1. A laminated film comprising:
a functional layer laminate having a wavelength conversion layer and a gas barrier film laminated on both main surfaces of the wavelength conversion layer so as to sandwich the wavelength conversion layer; and
an end face sealing layer covering a region from a portion of one main surface of the functional layer laminate to a portion of the other main surface including the entirety of end face of the functional layer laminate,
wherein the end face sealing layer has a build-up portion formed on the main surface of the functional layer laminate, and a width of the build-up portion measured from the end face is equal to or greater than 0.01 mm and equal to or smaller than 8% of a length of the main surface, and
a height of the end face sealing layer measured from the main surface in a direction perpendicular to the main surface is greater than 0% of a thickness of the functional layer laminate and equal to or smaller than 20% of the thickness of the functional layer laminate.

2. The laminated film according to claim 1,
wherein the end face sealing layer is constituted with multiple layers.

3. The laminated film according to claim 1,
wherein the functional layer laminate has a diffusion layer on at least one of the gas barrier films.

4. The laminated film according to claim 2,
wherein the functional layer laminate has a diffusion layer on at least one of the gas barrier films.
